(19) United States
(12) Patent Application Publication
(10) Pub. No.: US 2026/0359510 A1
(43) Pub. Date: Nov. 12, 2026

(54) Data Center Model Design with Physical Layout Optimization and Cabling Optimization

(71) Applicant: Oracle International Corporation, Redwood Shores, CA (US)

(72) Inventors: David Dale Becker, Seattle, WA (US); Jagwinder Singh Brar, Bellevue, WA (US)

(73) Assignee: Oracle International Corporation, Redwood Shores, CA (US)

(21) Appl. No.: 19/550,909

(22) Filed: Feb. 26, 2026

Related U.S. Application Data
(60) Provisional application No. 63/771,147, filed on Mar. 13, 2025.

(51) Int. Cl. G06F 30/18

(52) U.S. Cl. CPC G06F 30/18

(57) ABSTRACT

Techniques for designing and implementing cross-aisle client groups in a data center are disclosed. A system configures a client group of devices in a data center to span multiple rows of devices based on a data center model. A system develops the data center model based on a topology model and a physical layout model. The topology model describes device types and connections between devices. The physical layout model describes physical devices arranged in defined locations relative to each other and the physical cables that connect the devices to each other. The system configures a client group of network devices and client devices in a physical layout model to span multiple rows based on physical constraints associated with connection cables.

### INCORPORATION BY REFERENCE; DISCLAIMER

Each of the following applications and any parent patent applications (provisionals, non-provisionals, international, and foreign) to which this application claims priority to, directly or indirectly, are hereby incorporated by reference in their entirety to the same extent as if fully and explicitly recited herein. Any incorporation by reference is limited such that no subject matter is incorporated that is contrary to the explicit disclosure herein. The applications being incorporated by reference include at least: U.S. Application No. 63/771,147, filed on Mar. 13, 2025.

The Applicant hereby rescinds any disclaimer of claim scope in the parent application(s) or the prosecution history thereof and advises the USPTO that the claims in this application may be broader than any claim in the parent application(s).

### TECHNICAL FIELD

The present disclosure relates to configuring devices and cabling in data centers. In particular, the present disclosure relates to generating data center models that configure client groups across multiple rows based on transmission line specifications.

### BACKGROUND

Data centers are typically arranged into rows of compute racks (implementing clients) and network racks (implementing switches). A conventional physical arrangement includes, in a single row, (a) all clients of a client group and (b) the switches directly connected to those clients. This arrangement provides logical simplicity. In most arrangements, the network rack(s) are located at the end of the row.

Physical cables connect compute racks and network racks. Most data center arrangements use a combination of copper and fiber optic cabling to connect devices. Copper or high-speed ethernet cables are often used to connect a host to a switch when the distance between the two devices is short, whereas fiber optic cables are typically used for longer distance connections, for they experience less signal attenuation.

The approaches described in this section are approaches that could be pursued but not necessarily approaches that have been previously conceived or pursued. Therefore, unless otherwise indicated, it should not be assumed that any of the approaches described in this section qualify as prior art merely by virtue of their inclusion in this section.

### BRIEF DESCRIPTION OF DRAWINGS

The embodiments are illustrated by way of example and not by way of limitation in the figures of the accompanying drawings. References to “an” or “one” embodiment in this disclosure are not necessarily to the same embodiment, and they mean at least one. In the drawings:

FIG. 1 is a block diagram illustrating one pattern for implementing a cloud infrastructure as a service system according to at least one embodiment;

FIG. 2 is a block diagram illustrating another pattern for implementing a cloud infrastructure as a service system according to at least one embodiment;

FIG. 3 is a block diagram illustrating another pattern for implementing a cloud infrastructure as a service system according to at least one embodiment;

FIG. 4 is a block diagram illustrating another pattern for implementing a cloud infrastructure as a service system according to at least one embodiment;

FIG. 5 is a high-level diagram of a distributed environment showing a virtual or overlay cloud network hosted by a cloud service provider infrastructure according to certain embodiments;

FIG. 6 depicts a simplified architectural diagram of the physical components in the physical network within CI according to certain embodiments;

FIG. 7 depicts a simplified block diagram of a physical network provided by a CI according to certain embodiments;

FIG. 8 depicts a data center containing rows of compute racks and network racks with the network racks implementing a network fabric according to certain embodiments;

FIG. 9 depicts a block diagram that illustrates a computer system in accordance with one or more embodiments;

FIG. 10A-10I illustrate a system in accordance with one or more embodiments;

FIG. 11 illustrates an example set of operations for generating a data center model configuring client groups in a data center in accordance with one or more embodiments; and

FIG. 12A-12B illustrate an example embodiment in accordance with one or more embodiments.

### DETAILED DESCRIPTION

In the following description, for the purposes of explanation, numerous specific details are set forth to provide a thorough understanding. One or more embodiments may be practiced without these specific details. Features described in one embodiment may be combined with features described in a different embodiment. In some examples, well-known structures and devices are described with reference to a block diagram form to avoid unnecessarily obscuring the present disclosure.
1. INTRODUCTION
2. GENERAL OVERVIEW
3. EXAMPLES OF CLOUD INFRASTRUCTURE
4. EXAMPLES OF CLOUD NETWORKS
5. EXAMPLE NETWORK FABRICS
6. HARDWARE OVERVIEW
7. DATA CENTER MODEL ARCHITECTURE
8. GENERATING AND IMPLEMENTING A DATA CENTER MODEL INCLUDING CROSS-ROW CLIENT GROUPS GENERATIVE MODELS
9. EXAMPLE EMBODIMENT
10. MISCELLANEOUS; EXTENSIONS

### INTRODUCTION

In the following description, for the purposes of explanation, numerous specific details are set forth to provide a thorough understanding. One or more embodiments may be practiced without these specific details. Features described in one embodiment may be combined with features described in a different embodiment. In some examples, well-known structures and devices are described with reference to a block diagram form to avoid unnecessarily obscuring the present disclosure.

The term “cloud computing service” or “cloud service” generally refers to a service that is made available on demand, via scalable cloud infrastructure, typically over the internet or a private network, and managed by an external or in-house cloud provider (CP). The term “cloud infrastructure” (CI) generally refers to hardware and software components that provide computing, storage, and networking resources to deliver cloud services. There are various types or models of cloud services including Software-as-a-Service (SaaS), Platform-as-a-Service (PaaS), Infrastructure-as-a-Service (IaaS), Function-as-a-Service (FaaS), and others.

In a typical IaaS model, a CP provides virtualized and bare metal computing resources like servers, storage, and networking in a CP-operated data center. The CP is responsible for managing and maintaining the CI; the responsibilities span across multiple domains, such as operations, security, scalability, and compliance. Customers access the cloud services over the public Internet. Customers can use the CP CI to build their own customizable virtual or overlay networks and deploy customer resources. In other models, a CP provides similar virtualized and bare metal computing resources but in a customer-operated data center, which may include the customer's own CI. Customers access the CP CI and the customer CI over a private network. The combination of cloud services of the CP and the customer may be referred to as a “hybrid cloud.” In some cases, customers can serve as the CP's partner and sell the CP cloud services to further downstream customers. In yet other models, a first CP provides its virtualized and bare metal computing resources like servers, storage, and networking in the first CP's data center. A second CP provides its virtualized and bare metal computing resources also in the first CP's data center. A dedicated private network connects the CI of the two CPs. The combination of cloud services of the both CPs may be referred to as a “hybrid cloud.” In yet other models, a CP initially provisions CI to a customer, and then hands over all or a subset of the responsibilities associated with managing and maintaining the CI. For example, the customer may be primarily responsible for duties such as provisioning, repair, and maintenance of compute instances, while the CP retains other duties such as network management. Still other models may be used.

### General Overview

A network fabric may have multiple tiers, each tier including multiple fabric groups, each fabric group including multiple switches. The leaf tier includes client groups, each client group including multiple clients (e.g., computing servers, GPU servers, and/or end devices). Generally, switches within “tier n” connect with switches within “tier n+1”; and switches within “tier n” do not connect with each other. However, there are a variety of ways to make those specific connections. In an arrangement, a subset of switches in each leaf group is connected to every client in a subset of client groups. For example, every client in client group 1 is connected to switch 1 and switch 2 across all leaf groups; every client in client group 2 is connected to switch 3 and switch 4 across all leaf groups; etc.

Data transmission lines have different length-based performance characteristics based on the type of data transmission line. For example, one type of data transmission line may have an attenuation characteristic that reduces its reliability beyond a threshold length. In data centers, servers and switches may be arranged in rows that exceed threshold lengths for transmission lines. Embodiments configure a client group of devices in a data center to span multiple rows of devices based on a data center model. A system develops a data center model based on a topology model and a physical layout model. The topology model describes device types and connections between devices. The physical layout model describes physical devices arranged in defined locations relative to each other and the physical cables that connect the devices to each other. The system configures a client group of network devices and client devices in a physical layout model to span multiple rows based on physical constraints associated with connection cables. The connection cables are optimized based on distance limits and/or physical properties of Layer-1 technologies.

One embodiment improves space utilization and reliability characteristics of client groups in a data center by configuring two client groups to have an inverted symmetrical relationship with each other.

### Examples of Cloud Infrastructure

As noted above, infrastructure as a service (IaaS) is one particular type of cloud computing. For IaaS, the infrastructure (CI) provided by a CP can be configured to provide virtualized computing resources over a public network (e.g., the Internet). In an IaaS model, a CP can host the infrastructure components (e.g., servers, storage devices, network nodes (e.g., hardware), deployment software, platform virtualization (e.g., a hypervisor layer), or the like). CI thus provides infrastructure and a set of complementary cloud services that enable customers to build and run a wide range of applications and services in a highly available hosted distributed environment. The customer does not manage or control the underlying physical resources provided by CI but has control over operating systems, storage, and deployed applications; and possibly limited control of select networking components (e.g., firewalls).

In some cases, an IaaS provider may also supply a variety of services to accompany those infrastructure components (example services include billing software, monitoring software, logging software, load balancing software, clustering software, etc.). Thus, as these services may be policy-driven, IaaS users may be able to implement policies to drive load balancing to maintain application availability and performance. When a customer subscribes to or registers for an IaaS service provided by a CP, a tenancy, or account, is created for the customer. A tenancy is a secure and isolated partition within the CI where the customer can create, organize, and administer their cloud resources.

In some instances, IaaS customers may access resources and services through a wide area network (WAN), such as the Internet, and can use the cloud provider's services to install the remaining elements of an application stack. For example, the user can log in to the IaaS platform to create virtual machines (VMs), install operating systems (OSs) on each VM, deploy middleware such as databases, create storage buckets for workloads and backups, and even install enterprise software into that VM. Customers can then use the provider's services to perform various functions, including balancing network traffic, troubleshooting application issues, monitoring performance, managing disaster recovery, etc.

The CP may provide a console that enables customers and network administrators to configure, access, and manage resources deployed in the cloud using CI resources. In certain embodiments, the console provides a web-based user interface that can be used to access and manage CI. In some implementations, the console is a web-based application provided by the CP.

CI may support single-tenancy or multi-tenancy architectures. In a single tenancy architecture, a software (e.g., an application, a database) or a hardware component (e.g., a host machine or a server) of the CI serves a single customer or tenant. In a multi-tenancy architecture, a software or a hardware component of the CI serves multiple customers or tenants. Thus, in a multi-tenancy architecture, CI resources are shared between multiple customers or tenants. In a multi-tenancy situation, precautions are taken, and safeguards put in place within CI to ensure that each tenant's data is isolated and remains invisible to other tenants.

In certain embodiments, cloud resources within CI may include, for example, compute instances, block storage volumes, virtual cloud networks (VCNs), subnets, databases, third-party applications, SaaS applications, on-premise software, and web applications. Each cloud resource is assigned a unique identifier called a Cloud Identifier (CID). This identifier is included as part of the resource's information and can be used to manage the resource, for example, via a Console or through APIs. An example syntax for a CID is:

cid1.<RESOURCE TYPE>. <REALM>. [REGION][. FUTURE USE]. <UNIQUE ID>

where,
cid1: The literal string indicating the version of the CID;
resource type: The type of resource (for example, instance, volume, VCN, subnet, user, group, and so on);
realm: The realm the resource is in. Example values are “c1” for the commercial realm, “c2” for the Government Cloud realm, or “c3” for the Federal Government Cloud realm, etc. Each realm may have its own domain name;
region: The region the resource is in. If the region is not applicable to the resource, this part might be blank;
future use: Reserved for future use.
unique ID: The unique portion of the ID. The format may vary depending on the type of resource or service.

In some examples, IaaS deployment is the process of putting a new application, or a new version of an application, onto a prepared application server or the like. It may also include the process of preparing the server (e.g., installing libraries, daemons, etc.). This is often managed by the cloud provider, below the hypervisor layer (e.g., the servers, storage, network hardware, and virtualization). Thus, the customer may be responsible for handling (OS), middleware, and/or application deployment (e.g., on self-service virtual machines (e.g., that can be spun up on demand) or the like.

In some examples, IaaS provisioning may refer to acquiring computers or virtual hosts for use, and even installing needed libraries or services on them. In most cases, deployment does not include provisioning, and the provisioning may need to be performed first.

In some cases, there are two different challenges for IaaS provisioning. First, there is the initial challenge of provisioning the initial set of infrastructure before anything is running. Second, there is the challenge of evolving the existing infrastructure (e.g., adding new services, changing services, removing services, etc.) once everything has been provisioned. In some cases, these two challenges may be addressed by enabling the configuration of the infrastructure to be defined declaratively. In other words, the infrastructure (e.g., what components are needed and how they interact) can be defined by one or more configuration files. Thus, the overall topology of the infrastructure (e.g., what resources depend on which, and how they each work together) can be described declaratively. In some instances, once the topology is defined, a workflow can be generated that creates and/or manages the different components described in the configuration files.

In some examples, an infrastructure may have many interconnected elements. For example, there may be one or more virtual private clouds (VPCs) (e.g., a potentially on-demand pool of configurable and/or shared computing resources), also known as a core network. In some examples, there may also be one or more inbound/outbound traffic group rules provisioned to define how the inbound and/or outbound traffic of the network will be set up and one or more virtual machines (VMs). Other infrastructure elements may also be provisioned, such as a load balancer, a database, or the like. As more and more infrastructure elements are desired and/or added, the infrastructure may incrementally evolve.

In some instances, continuous deployment techniques may be employed to enable deployment of infrastructure code across various virtual computing environments. Additionally, the described techniques can enable infrastructure management within these environments. In some examples, service teams can write code that is desired to be deployed to one or more, but often many, different production environments (e.g., across various different geographic locations, sometimes spanning the entire world). However, in some examples, the infrastructure on which the code will be deployed must first be set up. In some instances, the provisioning can be done manually, a provisioning tool may be utilized to provision the resources, and/or deployment tools may be utilized to deploy the code once the infrastructure is provisioned.

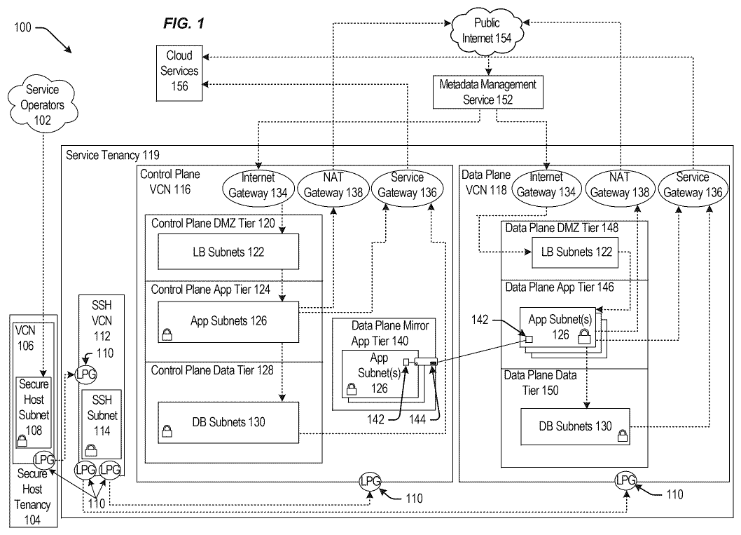

FIG. 1 is a block diagram 100 illustrating an example pattern of an IaaS architecture, according to at least one embodiment. Service operators 102 can be communicatively coupled to a secure host tenancy 104 that can include a virtual cloud network (VCN) 106 and a secure host subnet 108. In some examples, the service operators 102 may be using one or more client computing devices, which may be portable handheld devices (e.g., an iPhone®, cellular telephone, an iPad®, computing tablet, a personal digital assistant (PDA)) or wearable devices (e.g., a Google Glass® head mounted display), running software such as Microsoft Windows Mobile®, and/or a variety of mobile operating systems such as iOS, Windows Phone, Android, BlackBerry 8, Palm OS, and the like, and being Internet, e-mail, short message service (SMS), Blackberry®, or other communication protocol enabled. Alternatively, the client computing devices can be general purpose personal computers including, by way of example, personal computers and/or laptop computers running various versions of Microsoft Windows®, Apple Macintosh®, and/or Linux operating systems. The client computing devices can be workstation computers running any of a variety of commercially-available UNIX® or UNIX-like operating systems, including without limitation the variety of GNU/Linux operating systems, such as for example, Google Chrome OS. Alternatively, or in addition, client computing devices may be any other electronic device, such as a thin-client computer, an Internet-enabled gaming system (e.g., a Microsoft Xbox gaming console with or without a Kinect® gesture input device), and/or a personal messaging device, capable of communicating over a network that can access the VCN 106 and/or the Internet.

The VCN 106 can include a local peering gateway (LPG) 110 that can be communicatively coupled to a secure shell (SSH) VCN 112 via an LPG 110 contained in the SSH VCN 112. The SSH VCN 112 can include an SSH subnet 114, and the SSH VCN 112 can be communicatively coupled to a control plane VCN 116 via the LPG 110 contained in the control plane VCN 116. Also, the SSH VCN 112 can be communicatively coupled to a data plane VCN 118 via an LPG 110. The control plane VCN 116 and the data plane VCN 118 can be contained in a service tenancy 119 that can be owned and/or operated by the IaaS provider.

The control plane VCN 116 can include a control plane demilitarized zone (DMZ) tier 120 that acts as a perimeter network (e.g., portions of a corporate network between the corporate intranet and external networks). The DMZ-based servers may have restricted responsibilities and help keep breaches contained. Additionally, the DMZ tier 120 can include one or more load balancer (LB) subnet(s) 122, a control plane app tier 124 that can include app subnet(s) 126, a control plane data tier 128 that can include database (DB) subnet(s) 130 (e.g., frontend DB subnet(s) and/or backend DB subnet(s)). The LB subnet(s) 122 contained in the control plane DMZ tier 120 can be communicatively coupled to the app subnet(s) 126 contained in the control plane app tier 124 and an Internet gateway 134 that can be contained in the control plane VCN 116, and the app subnet(s) 126 can be communicatively coupled to the DB subnet(s) 130 contained in the control plane data tier 128 and a service gateway 136 and a network address translation (NAT) gateway 138. The control plane VCN 116 can include the service gateway 136 and the NAT gateway 138.

The control plane VCN 116 can include a data plane mirror app tier 140 that can include app subnet(s) 126. The app subnet(s) 126 contained in the data plane mirror app tier 140 can include a virtual network interface controller (VNIC) 142 that can execute a compute instance 144. The compute instance 144 can communicatively couple the app subnet(s) 126 of the data plane mirror app tier 140 to app subnet(s) 126 that can be contained in a data plane app tier 146.

The data plane VCN 118 can include the data plane app tier 146, a data plane DMZ tier 148, and a data plane data tier 150. The data plane DMZ tier 148 can include LB subnet(s) 122 that can be communicatively coupled to the app subnet(s) 126 of the data plane app tier 146 and the Internet gateway 134 of the data plane VCN 118. The app subnet(s) 126 can be communicatively coupled to the service gateway 136 of the data plane VCN 118 and the NAT gateway 138 of the data plane VCN 118. The data plane data tier 150 can also include the DB subnet(s) 130 that can be communicatively coupled to the app subnet(s) 126 of the data plane app tier 146.

The Internet gateway 134 of the control plane VCN 116 and of the data plane VCN 118 can be communicatively coupled to a metadata management service 152 that can be communicatively coupled to public Internet 154. Public Internet 154 can be communicatively coupled to the NAT gateway 138 of the control plane VCN 116 and of the data plane VCN 118. The service gateway 136 of the control plane VCN 116 and of the data plane VCN 118 can be communicatively couple to cloud services 156.

In some examples, the service gateway 136 of the control plane VCN 116 or of the data plane VCN 118 can make application programming interface (API) calls to cloud services 156 without going through public Internet 154. The API calls to cloud services 156 from the service gateway 136 can be one-way: the service gateway 136 can make API calls to cloud services 156, and cloud services 156 can send requested data to the service gateway 136. But, cloud services 156 may not initiate API calls to the service gateway 136.

In some examples, the secure host tenancy 104 can be directly connected to the service tenancy 119, which may be otherwise isolated. The secure host subnet 108 can communicate with the SSH subnet 114 through an LPG 110 that may enable two-way communication over an otherwise isolated system. Connecting the secure host subnet 108 to the SSH subnet 114 may give the secure host subnet 108 access to other entities within the service tenancy 119.

The control plane VCN 116 may allow users of the service tenancy 119 to set up or otherwise provision desired resources. Desired resources provisioned in the control plane VCN 116 may be deployed or otherwise used in the data plane VCN 118. In some examples, the control plane VCN 116 can be isolated from the data plane VCN 118, and the data plane mirror app tier 140 of the control plane VCN 116 can communicate with the data plane app tier 146 of the data plane VCN 118 via VNICs 142 that can be contained in the data plane mirror app tier 140 and the data plane app tier 146.

In some examples, users of the system, or customers, can make requests, for example create, read, update, or delete (CRUD) operations, through public Internet 154 that can communicate the requests to the metadata management service 152. The metadata management service 152 can communicate the request to the control plane VCN 116 through the Internet gateway 134. The request can be received by the LB subnet(s) 122 contained in the control plane DMZ tier 120. The LB subnet(s) 122 may determine that the request is valid, and in response to this determination, the LB subnet(s) 122 can transmit the request to app subnet(s) 126 contained in the control plane app tier 124. If the request is validated and requires a call to public Internet 154, the call to public Internet 154 may be transmitted to the NAT gateway 138 that can make the call to public Internet 154. Metadata that may be desired to be stored by the request can be stored in the DB subnet(s) 130.

In some examples, the data plane mirror app tier 140 can facilitate direct communication between the control plane VCN 116 and the data plane VCN 118. For example, changes, updates, or other suitable modifications to configuration may be desired to be applied to the resources contained in the data plane VCN 118. Via a VNIC 142, the control plane VCN 116 can directly communicate with, and can thereby execute the changes, updates, or other suitable modifications to configuration to, resources contained in the data plane VCN 118.

In some embodiments, the control plane VCN 116 and the data plane VCN 118 can be contained in the service tenancy 119. In this case, the user, or the customer, of the system may not own or operate either the control plane VCN 116 or the data plane VCN 118. Instead, the IaaS provider may own or operate the control plane VCN 116 and the data plane VCN 118, both of which may be contained in the service tenancy 119. This embodiment can enable isolation of networks that may prevent users or customers from interacting with other users', or other customers', resources. Also, this embodiment may allow users or customers of the system to store databases privately without needing to rely on public Internet 154, which may not have a desired level of threat prevention, for storage.

In other embodiments, the LB subnet(s) 122 contained in the control plane VCN 116 can be configured to receive a signal from the service gateway 136. In this embodiment, the control plane VCN 116 and the data plane VCN 118 may be configured to be called by a customer of the IaaS provider without calling public Internet 154. Customers of the IaaS provider may desire this embodiment since database(s) that the customers use may be controlled by the IaaS provider and may be stored on the service tenancy 119, which may be isolated from public Internet 154.

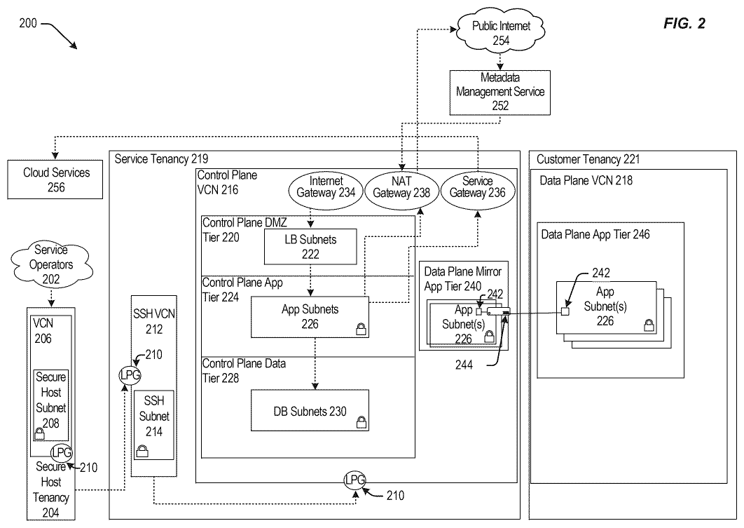

FIG. 2 is a block diagram 200 illustrating another example pattern of an IaaS architecture, according to at least one embodiment. Service operators 202 (e.g., service operators 102 of FIG. 1) can be communicatively coupled to a secure host tenancy 204 (e.g., the secure host tenancy 104 of FIG. 1) that can include a virtual cloud network (VCN) 206 (e.g., the VCN 106 of FIG. 1) and a secure host subnet 208 (e.g., the secure host subnet 108 of FIG. 1). The VCN 206 can include a local peering gateway (LPG) 210 (e.g., the LPG 110 of FIG. 1) that can be communicatively coupled to a secure shell (SSH) VCN 212 (e.g., the SSH VCN 112 of FIG. 1) via an LPG 110 contained in the SSH VCN 212. The SSH VCN 212 can include an SSH subnet 214 (e.g., the SSH subnet 114 of FIG. 1), and the SSH VCN 212 can be communicatively coupled to a control plane VCN 216 (e.g., the control plane VCN 116 of FIG. 1) via an LPG 210 contained in the control plane VCN 216. The control plane VCN 216 can be contained in a service tenancy 219 (e.g., the service tenancy 119 of FIG. 1), and the data plane VCN 218 (e.g., the data plane VCN 118 of FIG. 1) can be contained in a customer tenancy 221 that may be owned or operated by users, or customers, of the system.

The control plane VCN 216 can include a control plane DMZ tier 220 (e.g., the control plane DMZ tier 120 of FIG. 1) that can include LB subnet(s) 222 (e.g., LB subnet(s) 122 of FIG. 1), a control plane app tier 224 (e.g., the control plane app tier 124 of FIG. 1) that can include app subnet(s) 226 (e.g., app subnet(s) 126 of FIG. 1), a control plane data tier 228 (e.g., the control plane data tier 128 of FIG. 1) that can include database (DB) subnet(s) 230 (e.g., similar to DB subnet(s) 130 of FIG. 1). The LB subnet(s) 222 contained in the control plane DMZ tier 220 can be communicatively coupled to the app subnet(s) 226 contained in the control plane app tier 224 and an Internet gateway 234 (e.g., the Internet gateway 134 of FIG. 1) that can be contained in the control plane VCN 216, and the app subnet(s) 226 can be communicatively coupled to the DB subnet(s) 230 contained in the control plane data tier 228 and a service gateway 236 (e.g., the service gateway 136 of FIG. 1) and a network address translation (NAT) gateway 238 (e.g., the NAT gateway 138 of FIG. 1). The control plane VCN 216 can include the service gateway 236 and the NAT gateway 238.

The control plane VCN 216 can include a data plane mirror app tier 240 (e.g., the data plane mirror app tier 140 of FIG. 1) that can include app subnet(s) 226. The app subnet(s) 226 contained in the data plane mirror app tier 240 can include a virtual network interface controller (VNIC) 242 (e.g., the VNIC of 142) that can execute a compute instance 244 (e.g., similar to the compute instance 144 of FIG. 1). The compute instance 244 can facilitate communication between the app subnet(s) 226 of the data plane mirror app tier 240 and the app subnet(s) 226 that can be contained in a data plane app tier 246 (e.g., the data plane app tier 146 of FIG. 1) via the VNIC 242 contained in the data plane mirror app tier 240 and the VNIC 242 contained in the data plane app tier 246.

The Internet gateway 234 contained in the control plane VCN 216 can be communicatively coupled to a metadata management service 252 (e.g., the metadata management service 152 of FIG. 1) that can be communicatively coupled to public Internet 254 (e.g., public Internet 154 of FIG. 1). Public Internet 254 can be communicatively coupled to the NAT gateway 238 contained in the control plane VCN 216. The service gateway 236 contained in the control plane VCN 216 can be communicatively couple to cloud services 256 (e.g., cloud services 156 of FIG. 1).

In some examples, the data plane VCN 218 can be contained in the customer tenancy 221. In this case, the IaaS provider may provide the control plane VCN 216 for each customer, and the IaaS provider may, for each customer, set up a unique compute instance 244 that is contained in the service tenancy 219. Each compute instance 244 may allow communication between the control plane VCN 216, contained in the service tenancy 219, and the data plane VCN 218 that is contained in the customer tenancy 221. The compute instance 244 may allow resources, that are provisioned in the control plane VCN 216 that is contained in the service tenancy 219, to be deployed or otherwise used in the data plane VCN 218 that is contained in the customer tenancy 221.

In other examples, the customer of the IaaS provider may have databases that live in the customer tenancy 221. In this example, the control plane VCN 216 can include the data plane mirror app tier 240 that can include app subnet(s) 226. The data plane mirror app tier 240 can reside in the data plane VCN 218, but the data plane mirror app tier 240 may not live in the data plane VCN 218. That is, the data plane mirror app tier 240 may have access to the customer tenancy 221, but the data plane mirror app tier 240 may not exist in the data plane VCN 218 or be owned or operated by the customer of the IaaS provider. The data plane mirror app tier 240 may be configured to make calls to the data plane VCN 218 but may not be configured to make calls to any entity contained in the control plane VCN 216. The customer may desire to deploy or otherwise use resources in the data plane VCN 218 that are provisioned in the control plane VCN 216, and the data plane mirror app tier 240 can facilitate the desired deployment, or other usage of resources, of the customer.

In some embodiments, the customer of the IaaS provider can apply filters to the data plane VCN 218. In this embodiment, the customer can determine what the data plane VCN 218 can access, and the customer may restrict access to public Internet 254 from the data plane VCN 218. The IaaS provider may not be able to apply filters or otherwise control access of the data plane VCN 218 to any outside networks or databases. Applying filters and controls by the customer onto the data plane VCN 218, contained in the customer tenancy 221, can help isolate the data plane VCN 218 from other customers and from public Internet 254.

In some embodiments, cloud services 256 can be called by the service gateway 236 to access services that may not exist on public Internet 254, on the control plane VCN 216, or on the data plane VCN 218. The connection between cloud services 256 and the control plane VCN 216 or the data plane VCN 218 may not be live or continuous. Cloud services 256 may exist on a different network owned or operated by the IaaS provider. Cloud services 256 may be configured to receive calls from the service gateway 236 and may be configured to not receive calls from public Internet 254. Some cloud services 256 may be isolated from other cloud services 256, and the control plane VCN 216 may be isolated from cloud services 256 that may not be in the same region as the control plane VCN 216. For example, the control plane VCN 216 may be located in “Region 1,” and cloud service “Deployment 1,” may be located in Region 1 and in “Region 2.” If a call to Deployment 1 is made by the service gateway 236 contained in the control plane VCN 216 located in Region 1, the call may be transmitted to Deployment 1 in Region 1. In this example, the control plane VCN 216, or Deployment 1 in Region 1, may not be communicatively coupled to, or otherwise in communication with, Deployment 1 in Region 2.

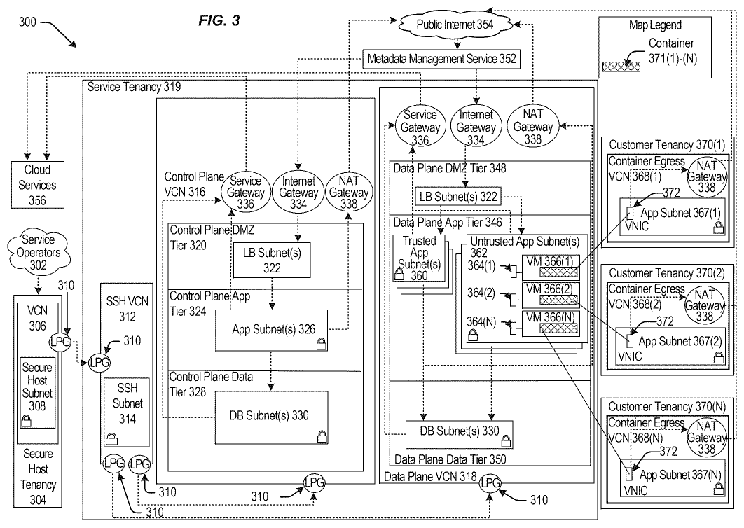

FIG. 3 is a block diagram 300 illustrating another example pattern of an IaaS architecture, according to at least one embodiment. Service operators 302 (e.g., service operators 102 of FIG. 1) can be communicatively coupled to a secure host tenancy 304 (e.g., the secure host tenancy 104 of FIG. 1) that can include a virtual cloud network (VCN) 306 (e.g., the VCN 106 of FIG. 1) and a secure host subnet 308 (e.g., the secure host subnet 108 of FIG. 1). The VCN 306 can include an LPG 310 (e.g., the LPG 110 of FIG. 1) that can be communicatively coupled to an SSH VCN 312 (e.g., the SSH VCN 112 of FIG. 1) via an LPG 310 contained in the SSH VCN 312. The SSH VCN 312 can include an SSH subnet 314 (e.g., the SSH subnet 114 of FIG. 1), and the SSH VCN 312 can be communicatively coupled to a control plane VCN 316 (e.g., the control plane VCN 116 of FIG. 1) via an LPG 310 contained in the control plane VCN 316 and to a data plane VCN 318 (e.g., the data plane 118 of FIG. 1) via an LPG 310 contained in the data plane VCN 318. The control plane VCN 316 and the data plane VCN 318 can be contained in a service tenancy 319 (e.g., the service tenancy 119 of FIG. 1).

The control plane VCN 316 can include a control plane DMZ tier 320 (e.g., the control plane DMZ tier 120 of FIG. 1) that can include load balancer (LB) subnet(s) 322 (e.g., LB subnet(s) 122 of FIG. 1), a control plane app tier 324 (e.g., the control plane app tier 124 of FIG. 1) that can include app subnet(s) 326 (e.g., similar to app subnet(s) 126 of FIG. 1), a control plane data tier 328 (e.g., the control plane data tier 128 of FIG. 1) that can include DB subnet(s) 330. The LB subnet(s) 322 contained in the control plane DMZ tier 320 can be communicatively coupled to the app subnet(s) 326 contained in the control plane app tier 324 and to an Internet gateway 334 (e.g., the Internet gateway 134 of FIG. 1) that can be contained in the control plane VCN 316, and the app subnet(s) 326 can be communicatively coupled to the DB subnet(s) 330 contained in the control plane data tier 328 and to a service gateway 336 (e.g., the service gateway of FIG. 1) and a network address translation (NAT) gateway 338 (e.g., the NAT gateway 138 of FIG. 1). The control plane VCN 316 can include the service gateway 336 and the NAT gateway 338.

The data plane VCN 318 can include a data plane app tier 346 (e.g., the data plane app tier 146 of FIG. 1), a data plane DMZ tier 348 (e.g., the data plane DMZ tier 148 of FIG. 1), and a data plane data tier 350 (e.g., the data plane data tier 150 of FIG. 1). The data plane DMZ tier 348 can include LB subnet(s) 322 that can be communicatively coupled to trusted app subnet(s) 360 and untrusted app subnet(s) 362 of the data plane app tier 346 and the Internet gateway 334 contained in the data plane VCN 318. The trusted app subnet(s) 360 can be communicatively coupled to the service gateway 336 contained in the data plane VCN 318, the NAT gateway 338 contained in the data plane VCN 318, and DB subnet(s) 330 contained in the data plane data tier 350. The untrusted app subnet(s) 362 can be communicatively coupled to the service gateway 336 contained in the data plane VCN 318 and DB subnet(s) 330 contained in the data plane data tier 350. The data plane data tier 350 can include DB subnet(s) 330 that can be communicatively coupled to the service gateway 336 contained in the data plane VCN 318.

The untrusted app subnet(s) 362 can include one or more primary VNICs 364(1)-(N) that can be communicatively coupled to tenant virtual machines (VMs) 366(1)-(N). Each tenant VM 366(1)-(N) can be communicatively coupled to a respective app subnet 367(1)-(N) that can be contained in respective container egress VCNs 368(1)-(N) that can be contained in respective customer tenancies 370(1)-(N). Respective secondary VNICs 372(1)-(N) can facilitate communication between the untrusted app subnet(s) 362 contained in the data plane VCN 318 and the app subnet contained in the container egress VCNs 368(1)-(N). Each container egress VCNs 368(1)-(N) can include a NAT gateway 338 that can be communicatively coupled to public Internet 354 (e.g., public Internet 154 of FIG. 1).

The Internet gateway 334 contained in the control plane VCN 316 and contained in the data plane VCN 318 can be communicatively coupled to a metadata management service 352 (e.g., the metadata management system 152 of FIG. 1) that can be communicatively coupled to public Internet 354. Public Internet 354 can be communicatively coupled to the NAT gateway 338 contained in the control plane VCN 316 and contained in the data plane VCN 318. The service gateway 336 contained in the control plane VCN 316 and contained in the data plane VCN 318 can be communicatively couple to cloud services 356.

In some embodiments, the data plane VCN 318 can be integrated with customer tenancies 370. This integration can be useful or desirable for customers of the IaaS provider in some cases such as a case that may desire support when executing code. The customer may provide code to run that may be destructive, may communicate with other customer resources, or may otherwise cause undesirable effects. In response to this, the IaaS provider may determine whether to run code given to the IaaS provider by the customer.

In some examples, the customer of the IaaS provider may grant temporary network access to the IaaS provider and request a function to be attached to the data plane app tier 346. Code to run the function may be executed in the VMs 366(1)-(N), and the code may not be configured to run anywhere else on the data plane VCN 318. Each VM 366(1)-(N) may be connected to one customer tenancy 370. Respective containers 371(1)-(N) contained in the VMs 366(1)-(N) may be configured to run the code. In this case, there can be a dual isolation (e.g., the containers 371(1)-(N) running code, where the containers 371(1)-(N) may be contained in at least the VM 366(1)-(N) that are contained in the untrusted app subnet(s) 362), which may help prevent incorrect or otherwise undesirable code from damaging the network of the IaaS provider or from damaging a network of a different customer. The containers 371(1)-(N) may be communicatively coupled to the customer tenancy 370 and may be configured to transmit or receive data from the customer tenancy 370. The containers 371(1)-(N) may not be configured to transmit or receive data from any other entity in the data plane VCN 318. Upon completion of running the code, the IaaS provider may kill or otherwise dispose of the containers 371(1)-(N).

In some embodiments, the trusted app subnet(s) 360 may run code that may be owned or operated by the IaaS provider. In this embodiment, the trusted app subnet(s) 360 may be communicatively coupled to the DB subnet(s) 330 and be configured to execute CRUD operations in the DB subnet(s) 330. The untrusted app subnet(s) 362 may be communicatively coupled to the DB subnet(s) 330, but in this embodiment, the untrusted app subnet(s) may be configured to execute read operations in the DB subnet(s) 330. The containers 371(1)-(N) that can be contained in the VM 366(1)-(N) of each customer and that may run code from the customer may not be communicatively coupled with the DB subnet(s) 330.

In other embodiments, the control plane VCN 316 and the data plane VCN 318 may not be directly communicatively coupled. In this embodiment, there may be no direct communication between the control plane VCN 316 and the data plane VCN 318. However, communication can occur indirectly through at least one method. An LPG 310 may be established by the IaaS provider that can facilitate communication between the control plane VCN 316 and the data plane VCN 318. In another example, the control plane VCN 316 or the data plane VCN 318 can make a call to cloud services 356 via the service gateway 336. For example, a call to cloud services 356 from the control plane VCN 316 can include a request for a service that can communicate with the data plane VCN 318.

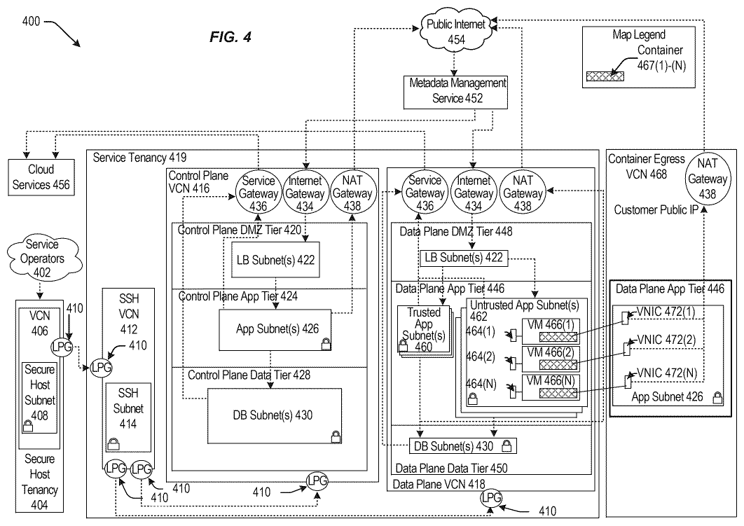

FIG. 4 is a block diagram 400 illustrating another example pattern of an IaaS architecture, according to at least one embodiment. Service operators 402 (e.g., service operators 102 of FIG. 1) can be communicatively coupled to a secure host tenancy 404 (e.g., the secure host tenancy 104 of FIG. 1) that can include a virtual cloud network (VCN) 406 (e.g., the VCN 106 of FIG. 1) and a secure host subnet 408 (e.g., the secure host subnet 108 of FIG. 1). The VCN 406 can include an LPG 410 (e.g., the LPG 110 of FIG. 1) that can be communicatively coupled to an SSH VCN 412 (e.g., the SSH VCN 112 of FIG. 1) via an LPG 410 contained in the SSH VCN 412. The SSH VCN 412 can include an SSH subnet 414 (e.g., the SSH subnet 114 of FIG. 1), and the SSH VCN 412 can be communicatively coupled to a control plane VCN 416 (e.g., the control plane VCN 116 of FIG. 1) via an LPG 410 contained in the control plane VCN 416 and to a data plane VCN 418 (e.g., the data plane 118 of FIG. 1) via an LPG 410 contained in the data plane VCN 418. The control plane VCN 416 and the data plane VCN 418 can be contained in a service tenancy 419 (e.g., the service tenancy 119 of FIG. 1).

The control plane VCN 416 can include a control plane DMZ tier 420 (e.g., the control plane DMZ tier 120 of FIG. 1) that can include LB subnet(s) 422 (e.g., LB subnet(s) 122 of FIG. 1), a control plane app tier 424 (e.g., the control plane app tier 124 of FIG. 1) that can include app subnet(s) 426 (e.g., app subnet(s) 126 of FIG. 1), a control plane data tier 428 (e.g., the control plane data tier 128 of FIG. 1) that can include DB subnet(s) 430 (e.g., DB subnet(s) 330 of FIG. 3). The LB subnet(s) 422 contained in the control plane DMZ tier 420 can be communicatively coupled to the app subnet(s) 426 contained in the control plane app tier 424 and to an Internet gateway 434 (e.g., the Internet gateway 134 of FIG. 1) that can be contained in the control plane VCN 416, and the app subnet(s) 426 can be communicatively coupled to the DB subnet(s) 430 contained in the control plane data tier 428 and to a service gateway 436 (e.g., the service gateway of FIG. 1) and a network address translation (NAT) gateway 438 (e.g., the NAT gateway 138 of FIG. 1). The control plane VCN 416 can include the service gateway 436 and the NAT gateway 438.

The data plane VCN 418 can include a data plane app tier 446 (e.g., the data plane app tier 146 of FIG. 1), a data plane DMZ tier 448 (e.g., the data plane DMZ tier 148 of FIG. 1), and a data plane data tier 450 (e.g., the data plane data tier 150 of FIG. 1). The data plane DMZ tier 448 can include LB subnet(s) 422 that can be communicatively coupled to trusted app subnet(s) 460 (e.g., trusted app subnet(s) 360 of FIG. 3) and untrusted app subnet(s) 462 (e.g., untrusted app subnet(s) 362 of FIG. 3) of the data plane app tier 446 and the Internet gateway 434 contained in the data plane VCN 418. The trusted app subnet(s) 460 can be communicatively coupled to the service gateway 436 contained in the data plane VCN 418, the NAT gateway 438 contained in the data plane VCN 418, and DB subnet(s) 430 contained in the data plane data tier 450. The untrusted app subnet(s) 462 can be communicatively coupled to the service gateway 436 contained in the data plane VCN 418 and DB subnet(s) 430 contained in the data plane data tier 450. The data plane data tier 450 can include DB subnet(s) 430 that can be communicatively coupled to the service gateway 436 contained in the data plane VCN 418.

The untrusted app subnet(s) 462 can include primary VNICs 464(1)-(N) that can be communicatively coupled to tenant virtual machines (VMs) 466(1)-(N) residing within the untrusted app subnet(s) 462. Each tenant VM 466(1)-(N) can run code in a respective container 467(1)-(N), and be communicatively coupled to an app subnet 426 that can be contained in a data plane app tier 446 that can be contained in a container egress VCN 468. Respective secondary VNICs 472(1)-(N) can facilitate communication between the untrusted app subnet(s) 462 contained in the data plane VCN 418 and the app subnet contained in the container egress VCN 468. The container egress VCN can include a NAT gateway 438 that can be communicatively coupled to public Internet 454 (e.g., public Internet 154 of FIG. 1).

The Internet gateway 434 contained in the control plane VCN 416 and contained in the data plane VCN 418 can be communicatively coupled to a metadata management service 452 (e.g., the metadata management system 152 of FIG. 1) that can be communicatively coupled to public Internet 454. Public Internet 454 can be communicatively coupled to the NAT gateway 438 contained in the control plane VCN 416 and contained in the data plane VCN 418. The service gateway 436 contained in the control plane VCN 416 and contained in the data plane VCN 418 can be communicatively couple to cloud services 456.

In some examples, the pattern illustrated by the architecture of block diagram 400 of FIG. 4 may be considered an exception to the pattern illustrated by the architecture of block diagram 300 of FIG. 3 and may be desirable for a customer of the IaaS provider if the IaaS provider cannot directly communicate with the customer (e.g., a disconnected region). The respective containers 467(1)-(N) that are contained in the VMs 466(1)-(N) for each customer can be accessed in real-time by the customer. The containers 467(1)-(N) may be configured to make calls to respective secondary VNICs 472(1)-(N) contained in app subnet(s) 426 of the data plane app tier 446 that can be contained in the container egress VCN 468. The secondary VNICs 472(1)-(N) can transmit the calls to the NAT gateway 438 that may transmit the calls to public Internet 454. In this example, the containers 467(1)-(N) that can be accessed in real-time by the customer can be isolated from the control plane VCN 416 and can be isolated from other entities contained in the data plane VCN 418. The containers 467(1)-(N) may also be isolated from resources from other customers.

In other examples, the customer can use the containers 467(1)-(N) to call cloud services 456. In this example, the customer may run code in the containers 467(1)-(N) that requests a service from cloud services 456. The containers 467(1)-(N) can transmit this request to the secondary VNICs 472(1)-(N) that can transmit the request to the NAT gateway that can transmit the request to public Internet 454. Public Internet 454 can transmit the request to LB subnet(s) 422 contained in the control plane VCN 416 via the Internet gateway 434. In response to determining the request is valid, the LB subnet(s) can transmit the request to app subnet(s) 426 that can transmit the request to cloud services 456 via the service gateway 436.

It should be appreciated that IaaS architectures 100, 200, 300, 400 depicted in the figures may have other components than those depicted. Further, the embodiments shown in the figures are only some examples of a cloud infrastructure system that may incorporate an embodiment of the disclosure. In some other embodiments, the IaaS systems may have more or fewer components than shown in the figures, may combine two or more components, or may have a different configuration or arrangement of components.

In certain embodiments, the IaaS systems described herein may include a suite of applications, middleware, and database service offerings that are delivered to a customer in a self-service, subscription-based, elastically scalable, reliable, highly available, and secure manner. An example of such an IaaS system is the Oracle Cloud Infrastructure (OCI) provided by the present assignee.

### Examples of Cloud Networks

As noted above, infrastructure as a service (IaaS) is one particular type of cloud computing service. In an IaaS model, customers can build their own customizable virtual or overlay networks and deploy customer resources over on-demand, scalable computing resources of CI.

The CI may comprise interconnected high-performance compute resources including various host machines, memory resources, and network resources that form a physical network, which is also referred to as a substrate network or an underlay network. The resources in CI may be spread across one or more data centers that may be geographically spread across one or more geographical regions. Virtualization software may be executed by these physical resources to provide a virtualized distributed environment. The virtualization creates an overlay network (also known as a software-based network, a software-defined network, or a virtual network) over the physical network. The CI physical network provides the underlying basis for creating one or more overlay or virtual networks on top of the physical network. The physical network (or substrate network or underlay network) comprises physical network devices such as physical switches, routers, computers and host machines, and the like. An overlay network is a logical (or virtual) network that runs on top of a physical substrate network. A given physical network can support one or multiple overlay networks. Overlay networks typically use encapsulation techniques to differentiate between traffic belonging to different overlay networks. A virtual or overlay network is also referred to as a virtual cloud network (VCN). The virtual networks are implemented using software virtualization technologies (e.g., hypervisors, virtualization functions implemented by network virtualization devices (NVDs) (e.g., smartNICs), top-of-rack (TOR) switches, smart TORs that implement one or more functions performed by an NVD, and other mechanisms) to create layers of network abstraction that can be run on top of the physical network. Virtual networks can take on many forms, including peer-to-peer networks, IP networks, and others. Virtual networks are typically either Layer-3 IP networks or Layer-2 VLANs. This method of virtual or overlay networking is often referred to as virtual or overlay Layer-3 networking. Examples of protocols developed for virtual networks include IP-in-IP (or Generic Routing Encapsulation (GRE)) Virtual Extensible LAN (VXLAN—IETF RFC 7348), Virtual Private Networks (VPNs) (e.g., MPLS Layer-3 Virtual Private Networks (RFC 4364)), VMware's NSX, GENEVE (Generic Network Virtualization Encapsulation), and others.

In a physical network, a network endpoint (“endpoint”) refers to a computing device or system that is connected to a physical network and communicates back and forth with the network to which it is connected. A network endpoint in the physical network may be connected to a Local Area Network (LAN), a Wide Area Network (WAN), or other type of physical network. Examples of traditional endpoints in a physical network include modems, hubs, bridges, switches, routers, and other networking devices, physical computers (or host machines), and the like. Each physical device in the physical network has a fixed network address that can be used to communicate with the device. This fixed network address can be a Layer-2 address (e.g., a MAC address), a fixed Layer-3 address (e.g., an IP address), and the like. In a virtualized environment or in a virtual network, the endpoints can include various virtual endpoints such as virtual machines that are hosted by components of the physical network (e.g., hosted by physical host machines). These endpoints in the virtual network are addressed by overlay addresses such as overlay Layer-2 addresses (e.g., overlay MAC addresses) and overlay Layer-3 addresses (e.g., overlay IP addresses). Network overlays enable flexibility by allowing network managers to move around the overlay addresses associated with network endpoints using software management (e.g., via software implementing a control plane for the virtual network). Accordingly, unlike in a physical network, in a virtual network, an overlay address (e.g., an overlay IP address) can be moved from one endpoint to another using network management software. Since the virtual network is built on top of a physical network, communications between components in the virtual network involves both the virtual network and the underlying physical network. In order to facilitate such communications, the components of CI are configured to learn and store mappings that map overlay addresses in the virtual network to actual physical addresses in the substrate network, and vice versa. These mappings are then used to facilitate the communications. Customer traffic is encapsulated to facilitate routing in the virtual network.

Accordingly, physical addresses (e.g., physical IP addresses) are associated with components in physical networks and overlay addresses (e.g., overlay IP addresses) are associated with entities in virtual or overlay networks. A physical IP address is an IP address associated with a physical device (e.g., a network device) in the substrate or physical network. For example, each NVD has an associated physical IP address. An overlay IP address is an overlay address associated with an entity in an overlay network, such as with a compute instance in a customer's virtual cloud network (VCN). Two different customers or tenants, each with their own private VCNs can potentially use the same overlay IP address in their VCNs without any knowledge of each other. Both the physical IP addresses and overlay IP addresses are types of real IP addresses. These are separate from virtual IP addresses. A virtual IP address is typically a single IP address that represents or maps to multiple real IP addresses. A virtual IP address provides a 1-to-many mapping between the virtual IP address and multiple real IP addresses. For example, a load balancer may use a VIP to map to or represent multiple servers, each server having its own real IP address.

The cloud infrastructure or CI is physically hosted in one or more data centers in one or more regions around the world. The CI may include components in the physical or substrate network and virtualized components (e.g., virtual networks, compute instances, virtual machines, etc.) that are in a virtual network built on top of the physical network components. In certain embodiments, the CI is organized and hosted in realms, regions, and availability domains.

When a customer subscribes to an IaaS service, resources from CI are provisioned for the customer and associated with the customer's tenancy. The customer can use these provisioned resources to build private networks and deploy resources on these networks. The customer networks that are hosted in the cloud by the CI are referred to as virtual cloud networks (VCNs). A customer can set up one or more virtual cloud networks (VCNs) using CI resources allocated for the customer. A VCN is a virtual or software defined private network. The customer resources that are deployed in the customer's VCN can include compute instances (e.g., virtual machines, bare-metal instances) and other resources. These compute instances may represent various customer workloads such as applications, load balancers, databases, and the like. A compute instance deployed on a VCN can communicate with publicly accessible endpoints (“public endpoints”) over a public network such as the Internet, with other instances in the same VCN or other VCNs (e.g., the customer's other VCNs, or VCNs not belonging to the customer), with the customer's on-premise data centers or networks, and with service endpoints, and other types of endpoints. CI thus offers high-performance compute resources and storage capacity in flexible virtual networks that are securely accessible from various networked locations such as from a customer's on-premise network.

The CP may provide various services using the CI. In some instances, customers of CI may themselves act like service providers and provide services using CI resources. A service provider may expose a service endpoint, which is characterized by identification information (e.g., an IP Address, a DNS name and port). A customer's resource (e.g., a compute instance) can consume a particular service by accessing a service endpoint exposed by the service for that particular service. These service endpoints are generally endpoints that are publicly accessible by users using public IP addresses associated with the endpoints via a public communication network such as the Internet. Network endpoints that are publicly accessible are also sometimes referred to as public endpoints. In certain implementations, a service endpoint provided for a service can be accessed by multiple customers that intend to consume that service. In other implementations, a dedicated service endpoint may be provided for a customer such that only that customer can access the service using that dedicated service endpoint.

In certain embodiments, when a VCN is created, it is associated with a private overlay Classless Inter-Domain Routing (CIDR) address space, which is a range of private overlay IP addresses that are assigned to the VCN (e.g., 10.0/16). A VCN includes associated subnets, route tables, and gateways. A VCN resides within a single region but can span one or more or all of the region's availability domains. A gateway is a virtual interface that is configured for a VCN and enables communication of traffic to and from the VCN to one or more endpoints outside the VCN. One or more different types of gateways may be configured for a VCN to enable communication to and from different types of endpoints.

A VCN can be subdivided into one or more sub-networks such as one or more subnets. A subnet is thus a unit of configuration or a subdivision that can be created within a VCN. A VCN can have one or multiple subnets. Each subnet within a VCN is associated with a contiguous range of overlay IP addresses (e.g., 10.0.0.0/24 and 10.0.1.0/24) that do not overlap with other subnets in that VCN, and which represent an address space subset within the address space of the VCN.

Each compute instance is associated with a virtual network interface card (VNIC), that enables the compute instance to participate in a subnet of a VCN. A VNIC is a logical representation of physical Network Interface Card (NIC). In general. a VNIC is an interface between an entity (e.g., a compute instance, a service) and a virtual network. A VNIC exists in a subnet, has one or more associated IP addresses, and associated security rules or policies. A VNIC is equivalent to a Layer-2 port on a switch. A VNIC is attached to a compute instance and to a subnet within a VCN. A VNIC associated with a compute instance enables the compute instance to be a part of a subnet of a VCN and enables the compute instance to communicate (e.g., send and receive packets) with endpoints that are on the same subnet as the compute instance, with endpoints in different subnets in the VCN, or with endpoints outside the VCN. The VNIC associated with a compute instance thus determines how the compute instance connects with endpoints inside and outside the VCN. A VNIC for a compute instance is created and associated with that compute instance when the compute instance is created and added to a subnet within a VCN. For a subnet comprising a set of compute instances, the subnet contains the VNICs corresponding to the set of compute instances, each VNIC attached to a compute instance within the set of computer instances.

Each compute instance is assigned a private overlay IP address via the VNIC associated with the compute instance. This private overlay IP address is assigned to the VNIC that is associated with the compute instance when the compute instance is created and used for routing traffic to and from the compute instance. All VNICs in a given subnet use the same route table, security lists, and DHCP options. As described above, each subnet within a VCN is associated with a contiguous range of overlay IP addresses (e.g., 10.0.0.0/24 and 10.0.1.0/24) that do not overlap with other subnets in that VCN, and which represent an address space subset within the address space of the VCN. For a VNIC on a particular subnet of a VCN, the private overlay IP address that is assigned to the VNIC is an address from the contiguous range of overlay IP addresses allocated for the subnet.

In certain embodiments, a compute instance may optionally be assigned additional overlay IP addresses in addition to the private overlay IP address, such as, for example, one or more public IP addresses if in a public subnet. These multiple addresses are assigned either on the same VNIC or over multiple VNICs that are associated with the compute instance. Each instance however has a primary VNIC that is created during instance launch and is associated with the overlay private IP address assigned to the instance—this primary VNIC cannot be removed. Additional VNICs, referred to as secondary VNICs, can be added to an existing instance in the same availability domain as the primary VNIC. All the VNICs are in the same availability domain as the instance. A secondary VNIC can be in a subnet in the same VCN as the primary VNIC, or in a different subnet that is either in the same VCN or a different one.

A compute instance may optionally be assigned a public IP address if it is in a public subnet. A subnet can be designated as either a public subnet or a private subnet at the time the subnet is created. A private subnet means that the resources (e.g., compute instances) and associated VNICs in the subnet cannot have public overlay IP addresses. A public subnet means that the resources and associated VNICs in the subnet can have public IP addresses. A customer can designate a subnet to exist either in a single availability domain or across multiple availability domains in a region or realm.

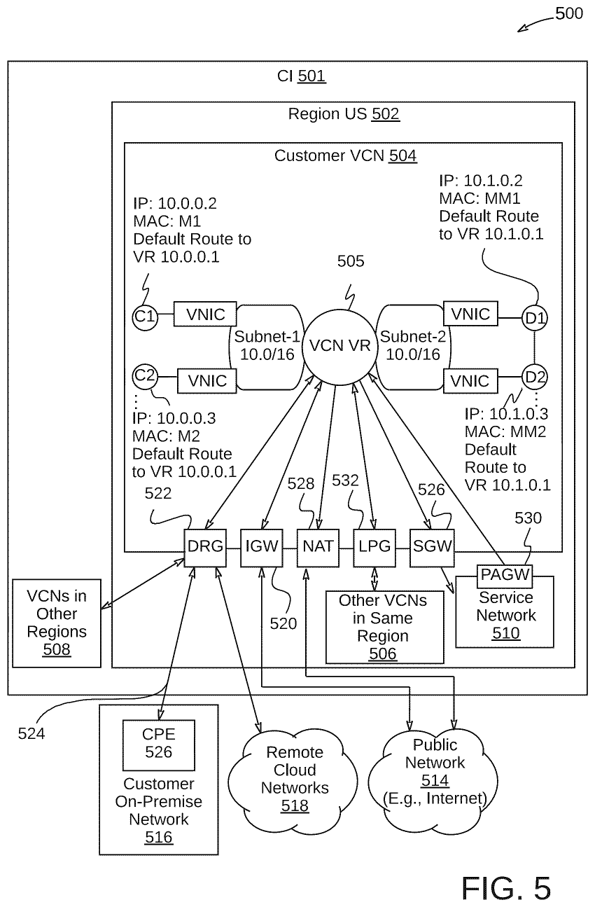

As described above, a VCN may be subdivided into one or more subnets. In certain embodiments, a Virtual Router (VR) configured for the VCN (referred to as the VCN VR or just VR) enables communications between the subnets of the VCN. For a subnet within a VCN, the VR represents a logical gateway for that subnet that enables the subnet (i.e., the compute instances on that subnet) to communicate with endpoints on other subnets within the VCN, and with other endpoints outside the VCN. The VCN VR is a logical entity that is configured to route traffic between VNICs in the VCN and virtual gateways (“gateways”) associated with the VCN. Gateways are further described below with respect to FIG. 5. A VCN VR is a Layer-3/IP Layer concept. In one embodiment, there is one VCN VR for a VCN where the VCN VR has potentially an unlimited number of ports addressed by IP addresses, with one port for each subnet of the VCN. In this manner, the VCN VR has a different IP address for each subnet in the VCN that the VCN VR is attached to. The VR is also connected to the various gateways configured for a VCN. In certain embodiments, a particular overlay IP address from the overlay IP address range for a subnet is reserved for a port of the VCN VR for that subnet. For example, consider a VCN having two subnets with associated address ranges 10.0/16 and 10.1/16, respectively. For the first subnet within the VCN with address range 10.0/16, an address from this range is reserved for a port of the VCN VR for that subnet. In some instances, the first IP address from the range may be reserved for the VCN VR. For example, for the subnet with overlay IP address range 10.0/16, IP address 10.0.0.1 may be reserved for a port of the VCN VR for that subnet. For the second subnet within the same VCN with address range 10.1/16, the VCN VR may have a port for that second subnet with IP address 10.1.0.1. The VCN VR has a different IP address for each of the subnets in the VCN.

In some other embodiments, each subnet within a VCN may have its own associated VR that is addressable by the subnet using a reserved or default IP address associated with the VR. The reserved or default IP address may, for example, be the first IP address from the range of IP addresses associated with that subnet. The VNICs in the subnet can communicate (e.g., send and receive packets) with the VR associated with the subnet using this default or reserved IP address. In such an embodiment, the VR is the ingress/egress point for that subnet. The VR associated with a subnet within the VCN can communicate with other VRs associated with other subnets within the VCN. The VRs can also communicate with gateways associated with the VCN. The VR function for a subnet is running on or executed by one or more NVDs executing VNICs functionality for VNICs in the subnet.

Route tables, security rules, and DHCP options may be configured for a VCN. Route tables are virtual route tables for the VCN and include rules to route traffic from subnets within the VCN to destinations outside the VCN by way of gateways or specially configured instances. A VCN's route tables can be customized to control how packets are forwarded/routed to and from the VCN. DHCP options refers to configuration information that is automatically provided to the instances when they boot up.

Security rules configured for a VCN represent overlay firewall rules for the VCN. The security rules can include ingress and egress rules, and specify the types of traffic (e.g., based upon protocol and port) that is allowed in and out of the instances within the VCN. The customer can choose whether a given rule is stateful or stateless. For instance, the customer can allow incoming SSH traffic from anywhere to a set of instances by setting up a stateful ingress rule with source CIDR 0.0.0.0/0, and destination TCP port 22. Security rules can be implemented using network security groups or security lists. A network security group consists of a set of security rules that apply only to the resources in that group. A security list, on the other hand, includes rules that apply to all the resources in any subnet that uses the security list. A VCN may be provided with a default security list with default security rules. DHCP options configured for a VCN provide configuration information that is automatically provided to the instances in the VCN when the instances boot up.

In certain embodiments, the configuration information for a VCN is determined and stored by a VCN Control Plane. The configuration information for a VCN may include, for example, information about the address range associated with the VCN, subnets within the VCN and associated information, one or more VRs associated with the VCN, compute instances in the VCN and associated VNICs, NVDs executing the various virtualization network functions (e.g., VNICs, VRs, gateways) associated with the VCN, state information for the VCN, and other VCN-related information. In certain embodiments, a VCN Distribution Service publishes the configuration information stored by the VCN Control Plane, or portions thereof, to the NVDs. The distributed information may be used to update information (e.g., forwarding tables, routing tables, etc.) stored and used by the NVDs to forward packets to and from the compute instances in the VCN.

In certain embodiments, the creation of VCNs and subnets are handled by a VCN Control Plane (CP), and the launching of compute instances is handled by a Compute Control Plane. The Compute Control Plane is responsible for allocating the physical resources for the compute instance and then calls the VCN Control Plane to create and attach VNICs to the compute instance. The VCN CP also sends VCN data mappings to the VCN data plane that is configured to perform packet forwarding and routing functions. In certain embodiments, the VCN CP provides a distribution service that is responsible for providing updates to the VCN data plane.

A customer may create one or more VCNs using resources hosted by CI. A compute instance deployed on a customer VCN may communicate with different endpoints. These endpoints can include endpoints that are hosted by CI and endpoints outside CI.

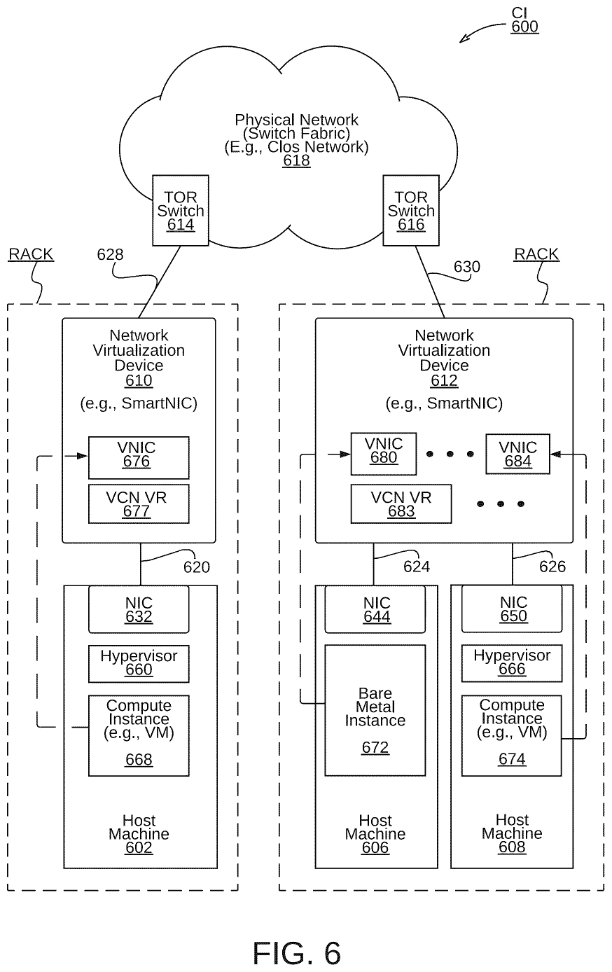

Various different architectures for implementing cloud-based service using CI are depicted in FIGS. 5-6, and are described below. FIG. 5 is a high-level diagram of a distributed environment 500 showing an overlay or customer VCN hosted by CI according to certain embodiments. The distributed environment depicted in FIG. 5 includes multiple components in the overlay network. Distributed environment 500 depicted in FIG. 5 is merely an example and is not intended to unduly limit the scope of claimed embodiments. Many variations, alternatives, and modifications are possible. For example, in some implementations, the distributed environment depicted in FIG. 5 may have more or fewer systems or components than those shown in FIG. 5, may combine two or more systems, or may have a different configuration or arrangement of systems.

As shown in the example depicted in FIG. 5, distributed environment 500 comprises CI 501 that provides services and resources that customers can subscribe to and use to build their virtual cloud networks (VCNs). In certain embodiments, CI 501 offers IaaS services to subscribing customers. The data centers within CI 501 may be organized into one or more regions. One example region “Region US” 502 is shown in FIG. 5. A customer has configured a customer VCN c/o Oracle International Corporation for region 502. The customer may deploy various compute instances on VCN 504, where the compute instances may include virtual machines or bare metal instances. Examples of instances include applications, database, load balancers, and the like.

In the embodiment depicted in FIG. 5, customer VCN 504 comprises two subnets, namely, “Subnet-1” and “Subnet-2”, each subnet with its own CIDR IP address range. In FIG. 5, the overlay IP address range for Subnet-1 is 10.0/16 and the address range for Subnet-2 is 10.1/16. A VCN Virtual Router 505 represents a logical gateway for the VCN that enables communications between subnets of the VCN 504, and with other endpoints outside the VCN. VCN VR 505 is configured to route traffic between VNICs in VCN 504 and gateways associated with VCN 504. VCN VR 505 provides a port for each subnet of VCN 504. For example, VR 505 may provide a port with IP address 10.0.0.1 for Subnet-1 and a port with IP address 10.1.0.1 for Subnet-2.

Multiple compute instances may be deployed on each subnet, where the compute instances can be virtual machine instances, and/or bare metal instances. The compute instances in a subnet may be hosted by one or more host machines within CI 501. A compute instance participates in a subnet via a VNIC associated with the compute instance. For example, as shown in FIG. 5, a compute instance C1 is part of Subnet-1 via a VNIC associated with the compute instance. Likewise, compute instance C2 is part of Subnet-1 via a VNIC associated with C2. In a similar manner, multiple compute instances, which may be virtual machine instances or bare metal instances, may be part of Subnet-1. Via its associated VNIC, each compute instance is assigned a private overlay IP address and a MAC address. For example, in FIG. 5, compute instance C1 has an overlay IP address of 10.0.0.2 and a MAC address of M1, while compute instance C2 has a private overlay IP address of 10.0.0.3 and a MAC address of M2. Each compute instance in Subnet-1, including compute instances C1 and C2, has a default route to VCN VR 505 using IP address 10.0.0.1, which is the IP address for a port of VCN VR 505 for Subnet-1.

Subnet-2 can have multiple compute instances deployed on it, including virtual machine instances and/or bare metal instances. For example, as shown in FIG. 5, compute instances D1 and D2 are part of Subnet-2 via VNICs associated with the respective compute instances. In the embodiment depicted in FIG. 5, compute instance D1 has an overlay IP address of 10.1.0.2 and a MAC address of MM 1, while compute instance D2 has a private overlay IP address of 10.1.0.3 and a MAC address of MM2. Each compute instance in Subnet-2, including compute instances D1 and D2, has a default route to VCN VR 505 using IP address 10.1.0.1, which is the IP address for a port of VCN VR 505 for Subnet-2.

VCN 504 may also include one or more load balancers. For example, a load balancer may be provided for a subnet and may be configured to load balance traffic across multiple compute instances on the subnet. A load balancer may also be provided to load balance traffic across subnets in the VCN.

A particular compute instance deployed on VCN 504 can communicate with various different endpoints. These endpoints may include endpoints that are hosted by CI 600 and endpoints outside CI 600. Endpoints that are hosted by CI 501 may include: an endpoint on the same subnet as the particular compute instance (e.g., communications between two compute instances in Subnet-1); an endpoint on a different subnet but within the same VCN (e.g., communication between a compute instance in Subnet-1 and a compute instance in Subnet-2); an endpoint in a different VCN in the same region (e.g., communications between a compute instance in Subnet-1 and an endpoint in a VCN in the same region 506 or 510, communications between a compute instance in Subnet-1 and an endpoint in service network 510 in the same region); or an endpoint in a VCN in a different region (e.g., communications between a compute instance in Subnet-1 and an endpoint in a VCN in a different region 508). A compute instance in a subnet hosted by CI 501 may also communicate with endpoints that are not hosted by CI 501 (i.e., are outside CI 501). These outside endpoints include endpoints in the customer's on-premise network 516, endpoints within other remote cloud hosted networks 518, public endpoints 514 accessible via a public network such as the Internet, and other endpoints.

Communications between compute instances on the same subnet are facilitated using VNICs associated with the source compute instance and the destination compute instance. For example, compute instance C1 in Subnet-1 may want to send packets to compute instance C2 in Subnet-1. For a packet originating at a source compute instance and whose destination is another compute instance in the same subnet, the packet is first processed by the VNIC associated with the source compute instance. Processing performed by the VNIC associated with the source compute instance can include determining destination information for the packet from the packet headers, identifying any policies (e.g., security lists) configured for the VNIC associated with the source compute instance, determining a next hop for the packet, performing any packet encapsulation/decapsulation functions as needed, and then forwarding/routing the packet to the next hop with the goal of facilitating communication of the packet to its intended destination. When the destination compute instance is in the same subnet as the source compute instance, the VNIC associated with the source compute instance is configured to identify the VNIC associated with the destination compute instance and forward the packet to that VNIC for processing. The VNIC associated with the destination compute instance is then executed and forwards the packet to the destination compute instance.

For a packet to be communicated from a compute instance in a subnet to an endpoint in a different subnet in the same VCN, the communication is facilitated by the VNICs associated with the source and destination compute instances and the VCN VR. For example, if compute instance C1 in Subnet-1 in FIG. 5 wants to send a packet to compute instance D1 in Subnet-2, the packet is first processed by the VNIC associated with compute instance C1. The VNIC associated with compute instance C1 is configured to route the packet to the VCN VR 505 using default route or port 10.0.0.1 of the VCN VR. VCN VR 505 is configured to route the packet to Subnet-2 using port 10.1.0.1. The packet is then received and processed by the VNIC associated with D1 and the VNIC forwards the packet to compute instance D1.

For a packet to be communicated from a compute instance in VCN 504 to an endpoint that is outside VCN 504, the communication is facilitated by the VNIC associated with the source compute instance, VCN VR 505, and gateways associated with VCN 504. One or more types of gateways may be associated with VCN 504. A gateway is an interface between a VCN and another endpoint, where another endpoint is outside the VCN. A gateway is a Layer-3/IP layer concept and enables a VCN to communicate with endpoints outside the VCN. A gateway thus facilitates traffic flow between a VCN and other VCNs or networks. Various different types of gateways may be configured for a VCN to facilitate different types of communications with different types of endpoints. Depending upon the gateway, the communications may be over public networks (e.g., the Internet) or over private networks. Various communication protocols may be used for these communications.

For example, compute instance C1 may want to communicate with an endpoint outside VCN 504. The packet may be first processed by the VNIC associated with source compute instance C1. The VNIC processing determines that the destination for the packet is outside the Subnet-1 of C1. The VNIC associated with C1 may forward the packet to VCN VR 505 for VCN 504. VCN VR 505 then processes the packet and as part of the processing, based upon the destination for the packet, determines a particular gateway associated with VCN 504 as the next hop for the packet. VCN VR 505 may then forward the packet to the particular identified gateway. For example, if the destination is an endpoint within the customer's on-premise network, then the packet may be forwarded by VCN VR 505 to Dynamic Routing Gateway (DRG) gateway 522 configured for VCN 504. The packet may then be forwarded from the gateway to a next hop to facilitate communication of the packet to it final intended destination.

Various different types of gateways may be configured for a VCN. Examples of gateways that may be configured for a VCN are depicted in FIG. 5 and described below. As shown in the embodiment depicted in FIG. 5, a Dynamic Routing Gateway (DRG) 522 may be added to or be associated with customer VCN 504 and provides a path for private network traffic communication between customer VCN 504 and another endpoint, where another endpoint can be the customer's on-premise network 516, a VCN 508 in a different region of CI 501, or other remote cloud networks 518 not hosted by CI 501. Customer on-premise network 516 may be a customer network or a customer data center built using the customer's resources. Access to customer on-premise network 516 is generally very restricted. For a customer that has both a customer on-premise network 516 and one or more VCNs 504 deployed or hosted in the cloud by CI 501, the customer may want their on-premise network 516 and their cloud based VCN 504 to be able to communicate with each other. This enables a customer to build an extended hybrid environment encompassing the customer's VCN 504 hosted by CI 501 and their on-premise network 516. DRG 522 enables this communication. To enable such communications, a communication channel 524 is set up where one endpoint of the channel is in customer on-premise network 516 and the other endpoint is in CI 501 and connected to customer VCN 504. Communication channel 524 can be over public communication networks such as the Internet or private communication networks. Various different communication protocols may be used such as IPsec VPN technology over a public communication network such as the Internet, Oracle's FastConnect technology that uses a private network instead of a public network, and others. The device or equipment in customer on-premise network 516 that forms one end point for communication channel 524 is referred to as the customer premise equipment (CPE), such as CPE 526 depicted in FIG. 5. On the CI 501 side, the endpoint may be a host machine executing DRG 522.

In certain embodiments, a Remote Peering Connection (RPC) can be added to a DRG, which allows a customer to peer one VCN with another VCN in a different region. Using such an RPC, customer VCN 504 can use DRG 522 to connect with a VCN 508 in another region. DRG 522 may also be used to communicate with other remote cloud networks 518, not hosted by CI 501 such as a Microsoft Azure cloud, Amazon AWS cloud, and others.

As shown in FIG. 5, an Internet Gateway (IGW) 520 may be configured for customer VCN 504 the enables a compute instance on VCN 504 to communicate with public endpoints 514 accessible over a public network such as the Internet. IGW 520 is a gateway that connects a VCN to a public network such as the Internet. IGW 520 enables a public subnet (where the resources in the public subnet have public overlay IP addresses) within a VCN, such as VCN 504, direct access to public endpoints 512 on a public network 514 such as the Internet. Using IGW 520, connections can be initiated from a subnet within VCN 504 or from the Internet.

A Network Address Translation (NAT) gateway 528 can be configured for customer's VCN 504 and enables cloud resources in the customer's VCN, which do not have dedicated public overlay IP addresses, access to the Internet and it does so without exposing those resources to direct incoming Internet connections (e.g., L4-L7 connections). This enables a private subnet within a VCN, such as private Subnet-1 in VCN 504, with private access to public endpoints on the Internet. In NAT gateways, connections can be initiated only from the private subnet to the public Internet and not from the Internet to the private subnet.

In certain embodiments, a Service Gateway (SGW) 526 can be configured for customer VCN 504 and provides a path for private network traffic between VCN 504 and supported services endpoints in a service network 510. In certain embodiments, service network 510 may be provided by the CP and may provide various services. An example of such a service network is Oracle's Services Network, which provides various services that can be used by customers. For example, a compute instance (e.g., a database system) in a private subnet of customer VCN 504 can back up data to a service endpoint (e.g., Object Storage) without needing public IP addresses or access to the Internet. In certain embodiments, a VCN can have only one SGW, and connections can only be initiated from a subnet within the VCN and not from service network 510. If a VCN is peered with another, resources in the other VCN typically cannot access the SGW. Resources in on-premise networks that are connected to a VCN with FastConnect or VPN Connect can also use the service gateway configured for that VCN.

In certain implementations, SGW 526 uses the concept of a service Classless Inter-Domain Routing (CIDR) label, which is a string that represents all the regional public IP address ranges for the service or group of services of interest. The customer uses the service CIDR label when they configure the SGW and related route rules to control traffic to the service. The customer can optionally utilize it when configuring security rules without needing to adjust them if the service's public IP addresses change in the future.

A Local Peering Gateway (LPG) 532 is a gateway that can be added to customer VCN 504 and enables VCN 504 to peer with another VCN in the same region. Peering means that the VCNs communicate using private IP addresses, without the traffic traversing a public network such as the Internet or without routing the traffic through the customer's on-premise network 516. In preferred embodiments, a VCN has a separate LPG for each peering it establishes. Local Peering or VCN Peering is a common practice used to establish network connectivity between different applications or infrastructure management functions.

Service providers, such as providers of services in service network 510, may provide access to services using different access models. According to a public access model, services may be exposed as public endpoints that are publicly accessible by compute instance in a customer VCN via a public network such as the Internet and or may be privately accessible via SGW 526. According to a specific private access model, services are made accessible as private IP endpoints in a private subnet in the customer's VCN. This is referred to as a Private Endpoint (PE) access and enables a service provider to expose their service as an instance in the customer's private network. A Private Endpoint resource represents a service within the customer's VCN. Each PE manifests as a VNIC (referred to as a PE-VNIC, with one or more private IPs) in a subnet chosen by the customer in the customer's VCN. A PE thus provides a way to present a service within a private customer VCN subnet using a VNIC. Since the endpoint is exposed as a VNIC, all the features associates with a VNIC such as routing rules, security lists, etc., are now available for the PE VNIC.

A service provider can register their service to enable access through a PE. The provider can associate policies with the service that restricts the service's visibility to the customer tenancies. A provider can register multiple services under a single virtual IP address (VIP), especially for multi-tenant services. There may be multiple such private endpoints (in multiple VCNs) that represent the same service.

Compute instances in the private subnet can then use the PE VNIC's private IP address or the service DNS name to access the service. Compute instances in the customer VCN can access the service by sending traffic to the private IP address of the PE in the customer VCN. A Private Access Gateway (PAGW) 530 is a gateway resource that can be attached to a service provider VCN (e.g., a VCN in service network 510) that acts as an ingress/egress point for all traffic from/to customer subnet private endpoints. PAGW 530 enables a provider to scale the number of PE connections without utilizing its internal IP address resources. A provider needs only configure one PAGW for any number of services registered in a single VCN. Providers can represent a service as a private endpoint in multiple VCNs of one or more customers. From the customer's perspective, the PE VNIC, which, instead of being attached to a customer's instance, appears attached to the service with which the customer wishes to interact. The traffic destined to the private endpoint is routed via PAGW 530 to the service. These are referred to as customer-to-service private connections (C2S connections).

The PE concept can also be used to extend the private access for the service to customer's on-premise networks and data centers, by allowing the traffic to flow through FastConnect/IPsec links and the private endpoint in the customer VCN. Private access for the service can also be extended to the customer's peered VCNs, by allowing the traffic to flow between LPG 532 and the PE in the customer's VCN.

A customer can control routing in a VCN at the subnet level, so the customer can specify which subnets in the customer's VCN, such as VCN 504, use each gateway. A VCN's route tables are used to decide if traffic is allowed out of a VCN through a particular gateway. For example, in a particular instance, a route table for a public subnet within customer VCN 504 may send non-local traffic through IGW 520. The route table for a private subnet within the same customer VCN 504 may send traffic destined for CP services through SGW 526. All remaining traffic may be sent via the NAT gateway 528. Route tables only control traffic going out of a VCN.

Security lists associated with a VCN are used to control traffic that comes into a VCN via a gateway via inbound connections. All resources in a subnet use the same route table and security lists. Security lists may be used to control specific types of traffic allowed in and out of instances in a subnet of a VCN. Security list rules may comprise ingress (inbound) and egress (outbound) rules. For example, an ingress rule may specify an allowed source address range, while an egress rule may specify an allowed destination address range. Security rules may specify a particular protocol (e.g., TCP, ICMP), a particular port (e.g., 22 for SSH, 3389 for Windows RDP), etc. In certain implementations, an instance's operating system may enforce its own firewall rules that are aligned with the security list rules. Rules may be stateful (e.g., a connection is tracked, and the response is automatically allowed without an explicit security list rule for the response traffic) or stateless.

Access from a customer VCN (i.e., by a resource or compute instance deployed on VCN 504) can be categorized as public access, private access, or dedicated access. Public access refers to an access model where a public IP address or a NAT is used to access a public endpoint. Private access enables customer workloads in VCN 504 with private IP addresses (e.g., resources in a private subnet) to access services without traversing a public network such as the Internet. In certain embodiments, CI 501 enables customer VCN workloads with private IP addresses to access the (public service endpoints of) services using a service gateway. A service gateway thus offers a private access model by establishing a virtual link between the customer's VCN and the service's public endpoint residing outside the customer's private network.

Additionally, CI may offer dedicated public access using technologies such as FastConnect public peering where customer on-premise instances can access one or more services in a customer VCN using a FastConnect connection and without traversing a public network such as the Internet. CI also may also offer dedicated private access using FastConnect private peering where customer on-premise instances with private IP addresses can access the customer's VCN workloads using a FastConnect connection. FastConnect is a network connectivity alternative to using the public Internet to connect a customer's on-premise network to CI and its services. FastConnect provides an easy, elastic, and economical way to create a dedicated and private connection with higher bandwidth options and a more reliable and consistent networking experience when compared to Internet-based connections.

FIG. 5 and the accompanying description above describes various virtualized components in an example virtual network. As described above, the virtual network is built on the underlying physical or substrate network. FIG. 6 depicts a simplified architectural diagram of the physical components in the physical network within CI 600 that provide the underlay for the virtual network according to certain embodiments. As shown, CI 600 provides a distributed environment comprising components and resources (e.g., compute, memory, and networking resources) provided by a cloud service provider (CP). These components and resources are used to provide cloud services (e.g., IaaS services) to subscribing customers, i.e., customers that have subscribed to one or more services provided by the CP. Based upon the services subscribed to by a customer, a subset of resources (e.g., compute, memory, and networking resources) of CI 600 are provisioned for the customer. Customers can then build their own cloud-based (i.e., CI-hosted) customizable and private virtual networks using physical compute, memory, and networking resources provided by CI 600. As previously indicated, these customer networks are referred to as virtual cloud networks (VCNs). A customer can deploy one or more customer resources, such as compute instances, on these customer VCNs. Compute instances can be in the form of virtual machines, bare metal instances, and the like. CI 600 provides infrastructure and a set of complementary cloud services that enable customers to build and run a wide range of applications and services in a highly available hosted environment.

In the example embodiment depicted in FIG. 6, the physical components of CI 600 include one or more physical host machines or physical servers (e.g., 602, 606, 608), network virtualization devices (NVDs) (e.g., 610, 612), top-of-rack (TOR) switches (e.g., 614, 616), and a physical network (e.g., 618), and switches in physical network 618. The physical host machines or servers may host and execute various compute instances that participate in one or more subnets of a VCN. The compute instances may include virtual machine instances, and bare metal instances. For example, the various compute instances depicted in FIG. 5 may be hosted by the physical host machines depicted in FIG. 6. The virtual machine compute instances in a VCN may be executed by one host machine or by multiple different host machines. The physical host machines may also host virtual host machines, container-based hosts or functions, and the like. The VNICs and VCN VR depicted in FIG. 5 may be executed by the NVDs depicted in FIG. 6. The gateways depicted in FIG. 5 may be executed by the host machines and/or by the NVDs depicted in FIG. 6.

The host machines or servers may execute a hypervisor (also referred to as a virtual machine monitor or VMM) that creates and enables a virtualized environment on the host machines. The virtualization or virtualized environment facilitates cloud-based computing. One or more compute instances may be created, executed, and managed on a host machine by a hypervisor on that host machine. The hypervisor on a host machine enables the physical computing resources of the host machine (e.g., compute, memory, and networking resources) to be shared between the various compute instances executed by the host machine.

For example, as depicted in FIG. 6, host machines 602 and 608 execute hypervisors 660 and 666, respectively. These hypervisors may be implemented using software, firmware, or hardware, or combinations thereof. Typically, a hypervisor is a process or a software layer that sits on top of the host machine's operating system (OS), which in turn executes on the hardware processors of the host machine. The hypervisor provides a virtualized environment by enabling the physical computing resources (e.g., processing resources such as processors/cores, memory resources, networking resources) of the host machine to be shared among the various virtual machine compute instances executed by the host machine. For example, in FIG. 6, hypervisor 660 may sit on top of the OS of host machine 602 and enables the computing resources (e.g., processing, memory, and networking resources) of host machine 602 to be shared between compute instances (e.g., virtual machines) executed by host machine 602. A virtual machine can have its own operating system (referred to as a guest operating system), which may be the same as or different from the OS of the host machine. The operating system of a virtual machine executed by a host machine may be the same as or different from the operating system of another virtual machine executed by the same host machine. A hypervisor thus enables multiple operating systems to be executed alongside each other while sharing the same computing resources of the host machine. The host machines depicted in FIG. 6 may have the same or different types of hypervisors.

A compute instance can be a virtual machine instance or a bare metal instance. In FIG. 6, compute instances 668 on host machine 602 and 674 on host machine 608 are examples of virtual machine instances. Host machine 606 is an example of a bare metal instance that is provided to a customer.

In certain instances, an entire host machine may be provisioned to a single customer, and all of the one or more compute instances (either virtual machines or bare metal instance) hosted by that host machine belong to that same customer. In other instances, a host machine may be shared between multiple customers (i.e., multiple tenants). In such a multi-tenancy scenario, a host machine may host virtual machine compute instances belonging to different customers. These compute instances may be members of different VCNs of different customers. In certain embodiments, a bare metal compute instance is hosted by a bare metal server without a hypervisor. When a bare metal compute instance is provisioned, a single customer or tenant maintains control of the physical CPU, memory, and network interfaces of the host machine hosting the bare metal instance and the host machine is not shared with other customers or tenants.

As previously described, each compute instance that is part of a VCN is associated with a VNIC that enables the compute instance to become a member of a subnet of the VCN. The VNIC associated with a compute instance facilitates the communication of packets or frames to and from the compute instance. A VNIC is associated with a compute instance when the compute instance is created. In certain embodiments, for a compute instance executed by a host machine, the VNIC associated with that compute instance is executed by an NVD connected to the host machine. For example, in FIG. 6, host machine 602 executes a virtual machine compute instance 668 that is associated with VNIC 676, and VNIC 676 is executed by NVD 610 connected to host machine 602. As another example, bare metal instance 672 hosted by host machine 606 is associated with VNIC 680 that is executed by NVD 612 connected to host machine 606. As yet another example, VNIC 684 is associated with compute instance 674 executed by host machine 608, and VNIC 684 is executed by NVD 612 connected to host machine 608.

For compute instances hosted by a host machine, an NVD connected to that host machine also executes VCN VRs corresponding to VCNs of which the compute instances are members. For example, in the embodiment depicted in FIG. 6, NVD 610 executes VCN VR 677 corresponding to the VCN of which compute instance 668 is a member. NVD 612 may also execute one or more VCN VRs 683 corresponding to VCNs corresponding to the compute instances hosted by host machines 606 and 608.

A host machine may include one or more network interface cards (NIC) that enable the host machine to be connected to other devices. A NIC on a host machine may provide one or more ports (or interfaces) that enable the host machine to be communicatively connected to another device. For example, a host machine may be connected to an NVD using one or more ports (or interfaces) provided on the host machine and on the NVD. A host machine may also be connected to other devices such as another host machine.

For example, in FIG. 6, host machine 602 is connected to NVD 610 using link 620 that extends between a port 634 provided by a NIC 632 of host machine 602 and between a port 636 of NVD 610. Host machine 606 is connected to NVD 612 using link 624 that extends between a port 646 provided by a NIC 644 of host machine 606 and between a port 648 of NVD 612. Host machine 608 is connected to NVD 612 using link 626 that extends between a port 652 provided by a NIC 650 of host machine 608 and between a port 654 of NVD 612.

The NVDs are in turn connected via communication links to top-of-the-rack (TOR) switches, which are connected to physical network 618 (also referred to as the switch fabric). In certain embodiments, the links between a host machine and an NVD, and between an NVD and a TOR switch are Ethernet links. For example, in FIG. 6, NVDs 610 and 612 are connected to TOR switches 614 and 616, respectively, using links 628 and 630. In certain embodiments, the links 620, 624, 626, 628, and 630 are Ethernet links. The collection of host machines and NVDs that are connected to a TOR is sometimes referred to as a rack.

Physical network 618 provides a communication fabric that enables TOR switches to communicate with each other. A communication fabric, also called network fabric or fabric, refers to a physical network structure that includes a set of interconnected switches that provide multiple redundant pathways for data flow between a set of computing devices. A fabric enables high-throughput, low-latency communication through structured, multi-path routing. A fabric has a topology that defines a physical layout and arrangement of the set of interconnected switches and links. The physical layout and arrangement of the set of interconnected switches and links define pathways for data to flow across the fabric. In an embodiment, physical network 618 can be a multi-tiered network. In certain implementations, physical network 618 is a multi-tiered Clos network of switches, with TOR switches 614 and 616 representing the leaf level nodes of the multi-tiered and multi-node physical switching network 618. Example network fabrics employing different network topologies, such as a Clos topology, are further described below in the Section titled “Example Network Fabrics.”

### Example Network Fabrics

Computing components located in the various racks of a data center are interconnected to one another by fabric. The term “network fabric” or “fabric” generally refers to a physical network structure that includes a set of interconnected switches that provide multiple redundant pathways for data flow between a set of computing devices. A fabric enables high-throughput, low-latency communication through structured, multi-path routing.

A fabric is associated with a topology that defines a physical layout and arrangement of the set of interconnected switches and links. The physical layout and arrangement of the set of interconnected switches and links define pathways for data to flow across the fabric. An example network topology is multi-tiered Clos topology. A multi-tiered Clos topology is a type of non-blocking, multistage or multi-tiered switching network topology, where the number of stages or tiers can be two, three, four, five, etc. A Clos network with “n” stages may be referred to as a “n”-tiered network. Each switch in “tier n” is connected to each switch in “tier n+1.” In a 2-tier spine, t1 may be referred to a leaf layer, and t2 may be referred to as a spine layer. The spine layer can server as a high-speed backbone, interacting with the leaf layer.

A fabric can include different groups of switches and clients, referred to as “fabric groups” and “client groups,” arranged in various variations or arrangements of network topologies. Each tier of the fabric includes one or more fabric groups. The leaf tier includes one or more client groups (e.g., computing servers, GPU servers, and/or end devices). A “role” of a fabric group is associated with the tier of the fabric group. For example, a role of a fabric group in t1 may be “leaf,” and a role of a fabric group in t2 may be “spine.”

Each fabric group has a defined number of switches. Each switch has one or more south-facing ports, also called “downlinks,” and one or more north-facing ports, also called “uplinks.” The south-facing ports of switches in a fabric group of an upper tier may be connected to the north-facing ports of switches in a fabric group of a lower tier.

The configuration of connections between switches of fabric groups of adjacent tiers may be referred to as “linking configurations” or “linking rules.” Examples of linking configurations include a full mesh configuration, or a partial mesh configuration. In a full mesh configuration, every south-facing port of switches of an upper fabric group is directly connected to every north-facing port of switches of a lower fabric group. The non-blocking configuration allows connections to be made between switches in adjacent tiers without interference from currently established connections. Various cablings options may be used to implement the links, such as Active Optical Connectors (AOCs); high-speed optical transceivers that uses Coarse Wavelength Division Multiplexing (CWDM); and/or high-speed, hot-pluggable, low-power-dissipation optical transceivers.

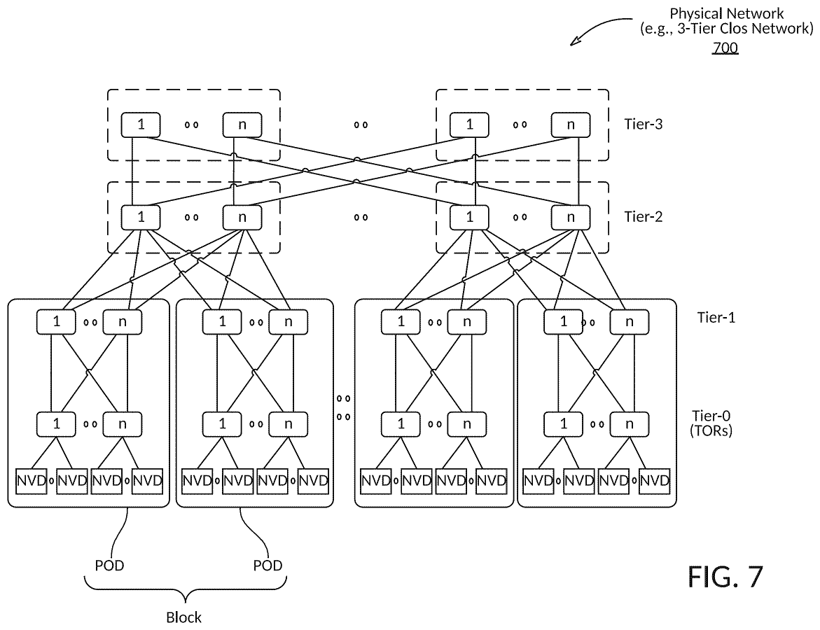

FIG. 7 depicts a simplified block diagram of a physical network 700 structured as a Clos network according to certain embodiments. The embodiment depicted in FIG. 7 is a 3-tiered network comprising tiers 1, 2, and 3. The TOR switches represent Tier-0 switches in the Clos network. One or more NVDs are connected to the TOR switches. Tier-0 switches are also referred to as edge devices of the physical network. The Tier-0 switches are connected to Tier-1 switches (also referred to as leaf switches). In the embodiment depicted in FIG. 7, a set of “n” Tier-0 TOR switches are connected to a set of “n” Tier-1 switches and together form a pod. Each Tier-0 switch in a pod is interconnected to all the Tier-1 switches in the pod, but there is no connectivity of switches between pods. In certain implementations, two pods are referred to as a block. Each block is served by or connected to a set of “n” Tier-2 switches (sometimes referred to as spine switches). There can be several blocks in the physical network topology. The Tier-2 switches are in turn connected to “n” Tier-3 switches (sometimes referred to as super-spine switches). Communication of packets over physical network 500 is typically performed using one or more Layer-3 communication protocols. Typically, all the layers of the physical network, except for the TORs layer are n-ways redundant thus allowing for high availability. Policies may be specified for pods and blocks to control the visibility of switches to each other in the physical network so as to enable scaling of the physical network.

A feature of a Clos network is that the maximum hop count to reach from one Tier-0 switch to another Tier-0 switch (or from an NVD connected to a Tier-0 switch to another NVD connected to a Tier-0 switch) is fixed. For example, in a 3-Tiered Clos network at most seven hops are needed for a packet to reach from one NVD to another NVD, where the source and target NVDs are connected to the leaf tier of the Clos network. Likewise, in a 4-tiered Clos network, at most nine hops are needed for a packet to reach from one NVD to another NVD, where the source and target NVDs are connected to the leaf tier of the Clos network. Thus, a Clos network architecture maintains consistent latency throughout the network, which is important for communication within and between data centers. A Clos topology scales horizontally and is cost effective. The bandwidth/throughput capacity of the network can be easily increased by adding more switches at the various tiers (e.g., more leaf and spine switches) and by increasing the number of links between the switches at adjacent tiers.

In an embodiment, a single site implements multiple networks, each implemented by one or more network fabrics. Each network in a site may serve a different purpose, such as a front-end network, a back-end network, a management network, and/or other networks. Each network fabric in a site may be implemented using a different network topology or a different combination of network topologies.

As examples, a compute network fabric architecture (CNFA) is configured to connect with non-network racks (compute, storage, service enclave, etc.) within a datacenter. CNFA may be implemented as a 3-tier Clos network. A junction network fabric architecture (JNFA) is configured to connect with network device roles, including: CNFAs; internet gateways; dedicated private connections to on-premise datacenters of customers; and backbone devices. JNFA may be implemented as a 2-tier Clos network. A management network fabric architecture (MNFA) is configured to connect with management devices. In an example, a site includes a CNFA, JNDA, and MNFA. The CNFA may include multiple (e.g., six) blocks. For external connectivity, a subset of t2 blocks (e.g., one t2 block) of the CNFA in a site is dedicated to connecting to t1 switches of the JNFA (rather than t3 super-spine switches of the CNFA, as described above). Further, one or more t1 switches of the JNFA are dedicated to connecting to t1 switches of the MNFA.

As further examples, performance network fabric architectures (PNFA) may be used. PNFA provides connectivity for cluster networks, such as high-performance computer (HPC) networks, high-performance database platform networks, and GPU networks. PNFA enables fine-grained traffic engineering that supports Quality of Service (QoS), which is a set of technologies that manage network traffic to prioritize critical applications. PNFA supports RDMA over Converged Ethernet (e.g., RoCE v1 and/or ROCEv2), Virtual eXtensible Local-Area Network (VXLAN), dynamic load balancing (DLB), Dot1x, etc. Different variants of PNFA have different numbers of tiers, e.g., two, three. In an example, a site may include a CNFA and a PNFA. “RDMA” or “Remote Direct Memory Access” generally refers to a technology that allows computing devices to access each other's memory directly without using the operating system.

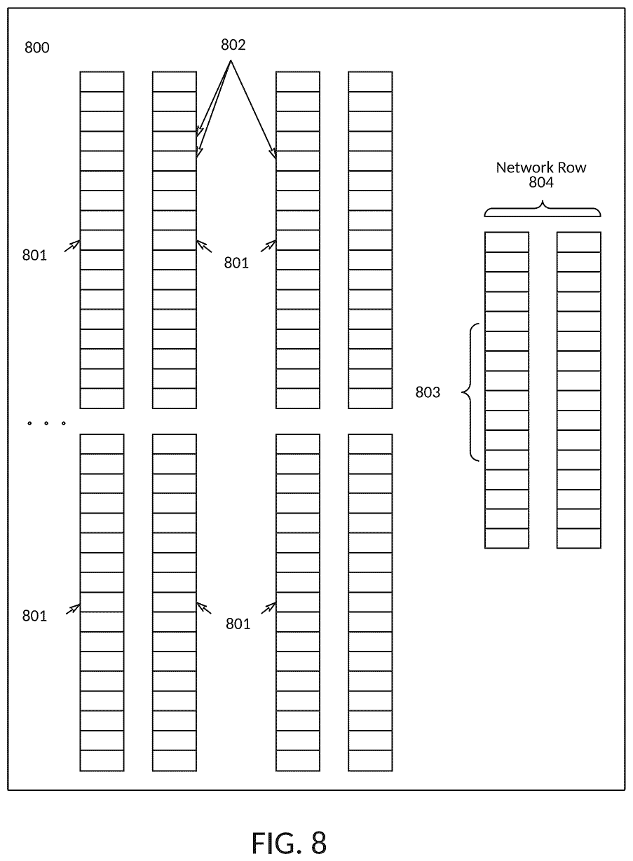

A fabric topology is implemented by physical racks of switches. In an embodiment, each block of switches in a network fabric is implemented in separate racks within a datacenter. FIG. 8 depicts a data hall 800 containing rows of compute racks and network racks, with the network racks implementing a network fabric, according to certain embodiments. The leaf block racks 801 may be located on the data hall floor adjacent to host-containing racks 802, effectively providing the data hall with functionality of an intermediate distribution frame (IDF). The spine block racks 803 may be located in a network row 804 in the data hall 800, effectively providing the data hall with functionality of a main distribution frame (MDF). Several data halls can be combined to provide a data center with a larger capacity.

### Hardware Overview

According to one embodiment, the techniques described herein are implemented by one or more special-purpose computing devices. The special-purpose computing devices may be hard-wired to perform the techniques, or may include digital electronic devices such as one or more application-specific integrated circuits (ASICs), field programmable gate arrays (FPGAs), or network processing units (NPUs) that are persistently programmed to perform the techniques, or may include one or more general purpose hardware processors programmed to perform the techniques pursuant to program instructions in firmware, memory, other storage, or a combination. Such special-purpose computing devices may also combine custom hard-wired logic, ASICs, FPGAs, or NPUs with custom programming to accomplish the techniques. The special-purpose computing devices may be desktop computer systems, portable computer systems, handheld devices, networking devices or any other device that incorporates hard-wired and/or program logic to implement the techniques.

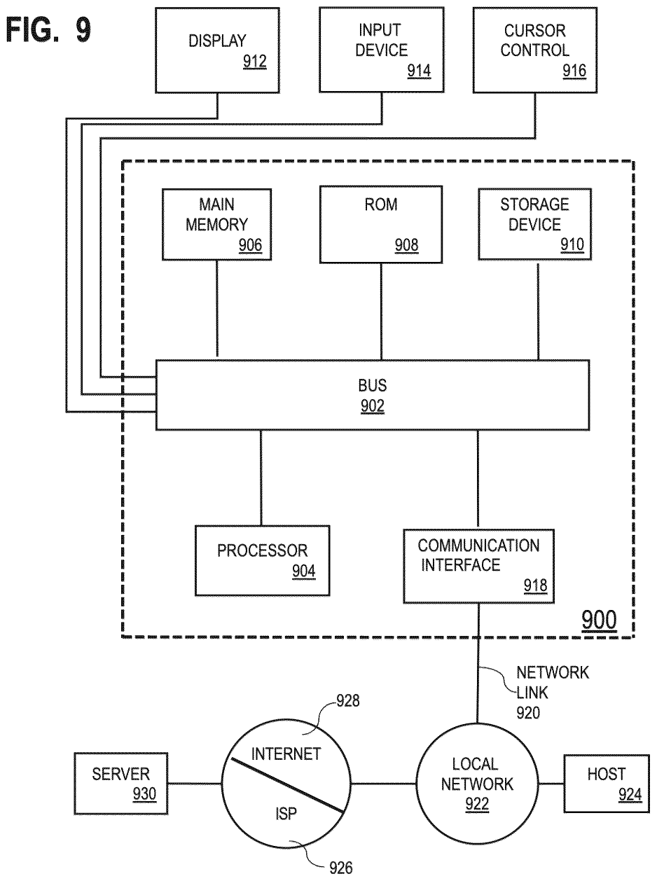

For example, FIG. 9 is a block diagram that illustrates a computer system 900 upon which an embodiment of the disclosure may be implemented. Computer system 900 includes a bus 902 or other communication mechanism for communicating information, and a hardware processor 904 coupled with bus 902 for processing information. Hardware processor 904 may be, for example, a general purpose microprocessor.

Computer system 900 also includes a main memory 906, such as a random access memory (RAM) or other dynamic storage device, coupled to bus 902 for storing information and instructions to be executed by processor 904. Main memory 906 also may be used for storing temporary variables or other intermediate information during execution of instructions to be executed by processor 904. Such instructions, when stored in non-transitory storage media accessible to processor 904, render computer system 900 into a special-purpose machine that is customized to perform the operations specified in the instructions.

Computer system 900 further includes a read-only memory (ROM) 908 or other static storage device coupled to bus 902 for storing static information and instructions for processor 904. A storage device 910, such as a magnetic disk, optical disk, or a solid-state drive (SSD) is provided and coupled to bus 902 for storing information and instructions.

Computer system 900 may be coupled via bus 902 to a display 912, such as a cathode ray tube (CRT), for displaying information to a computer user. An input device 914, including alphanumeric and other keys, is coupled to bus 902 for communicating information and command selections to processor 904. Another type of user input device is cursor control 916, such as a mouse, a trackball, or cursor direction keys for communicating direction information and command selections to processor 904 and for controlling cursor movement on display 912. This input device typically has two degrees of freedom in two axes, a first axis (e.g., x) and a second axis (e.g., y), that allows the device to specify positions in a plane.

Computer system 900 may implement the techniques described herein using customized hard-wired logic, one or more ASICs or FPGAs, firmware and/or program logic which in combination with the computer system causes or programs computer system 900 to be a special-purpose machine. According to one embodiment, the techniques herein are performed by computer system 900 in response to processor 904 executing one or more sequences of one or more instructions contained in main memory 906. Such instructions may be read into main memory 906 from another storage medium, such as storage device 910. Execution of the sequences of instructions contained in main memory 906 causes processor 904 to perform the process steps described herein. In alternative embodiments, hard-wired circuitry may be used in place of or in combination with software instructions.

The term “storage media” as used herein refers to any non-transitory media that store data and/or instructions that cause a machine to operate in a specific fashion. Such storage media may comprise non-volatile media and/or volatile media. Non-volatile media includes, for example, optical or magnetic disks, such as storage device 910. Volatile media includes dynamic memory, such as main memory 906. Common forms of storage media include, for example, a floppy disk, a flexible disk, hard disk, SSD, magnetic tape, or any other magnetic data storage medium, a CD-ROM, any other optical data storage medium, any physical medium with patterns of holes, a RAM, a PROM, and EPROM, a FLASH-EPROM, NVRAM, any other memory chip or cartridge, content-addressable memory (CAM), and ternary content-addressable memory (TCAM).

Storage media is distinct from but may be used in conjunction with transmission media. Transmission media participates in transferring information between storage media. For example, transmission media includes coaxial cables, copper wire and fiber optics, including the wires that comprise bus 902. Transmission media can also take the form of acoustic or light waves, such as those generated during radio-wave and infra-red data communications.

Various forms of media may be involved in carrying one or more sequences of one or more instructions to processor 904 for execution. For example, the instructions may initially be carried on a magnetic disk or SSD of a remote computer. The remote computer can load the instructions into its dynamic memory and send the instructions over a telephone line using a modem. A modem local to computer system 900 can receive the data on the telephone line and use an infra-red transmitter to convert the data to an infra-red signal. An infra-red detector can receive the data carried in the infra-red signal and appropriate circuitry can place the data on bus 902. Bus 902 carries the data to main memory 906, from which processor 904 retrieves and executes the instructions. The instructions received by main memory 906 may optionally be stored on storage device 910 either before or after execution by processor 904.

Computer system 900 also includes a communication interface 918 coupled to bus 902. Communication interface 918 provides a two-way data communication coupling to a network link 920 that is connected to a local network 922. For example, communication interface 918 may be an integrated services digital network (ISDN) card, cable modem, satellite modem, or a modem to provide a data communication connection to a corresponding type of telephone line. As another example, communication interface 918 may be a local area network (LAN) card to provide a data communication connection to a compatible LAN. Wireless links may also be implemented. In any such implementation, communication interface 918 sends and receives electrical, electromagnetic or optical signals that carry digital data streams representing various types of information.

Network link 920 typically provides data communication through one or more networks to other data devices. For example, network link 920 may provide a connection through local network 922 to a host computer 924 or to data equipment operated by an Internet Service Provider (ISP) 926. ISP 926 in turn provides data communication services through the world wide packet data communication network now commonly referred to as the “Internet” 928. Local network 922 and Internet 928 both use electrical, electromagnetic or optical signals that carry digital data streams. The signals through the various networks and the signals on network link 920 and through communication interface 918, which carry the digital data to and from computer system 900, are example forms of transmission media.

Computer system 900 can send messages and receive data, including program code, through the network(s), network link 920 and communication interface 918. In the Internet example, a server 930 might transmit a requested code for an application program through Internet 928, ISP 926, local network 922 and communication interface 918.

The received code may be executed by processor 904 as it is received, and/or stored in storage device 910, or other non-volatile storage for later execution.

### Data Center Model Architecture

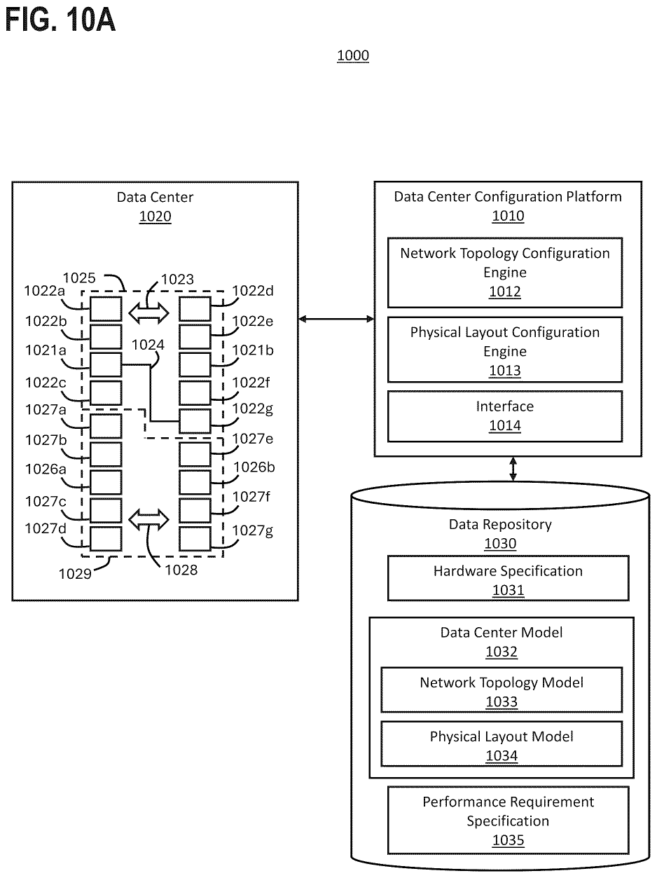

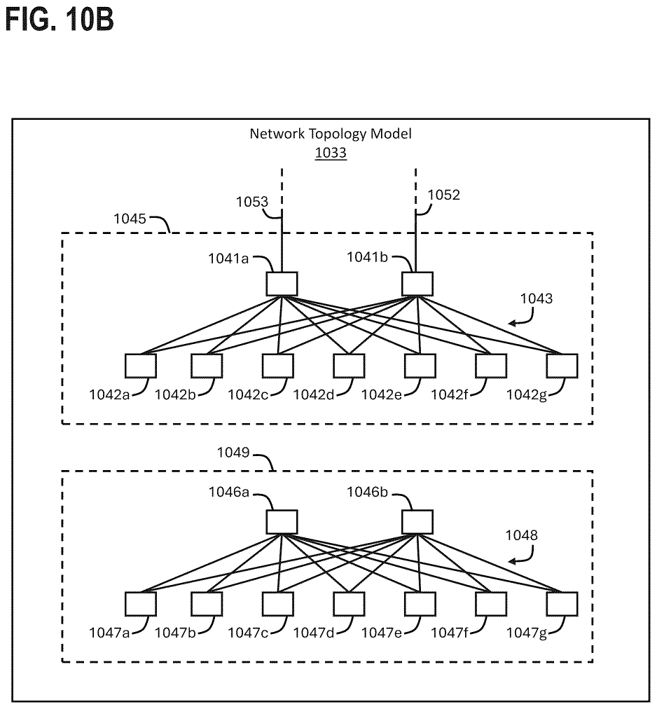

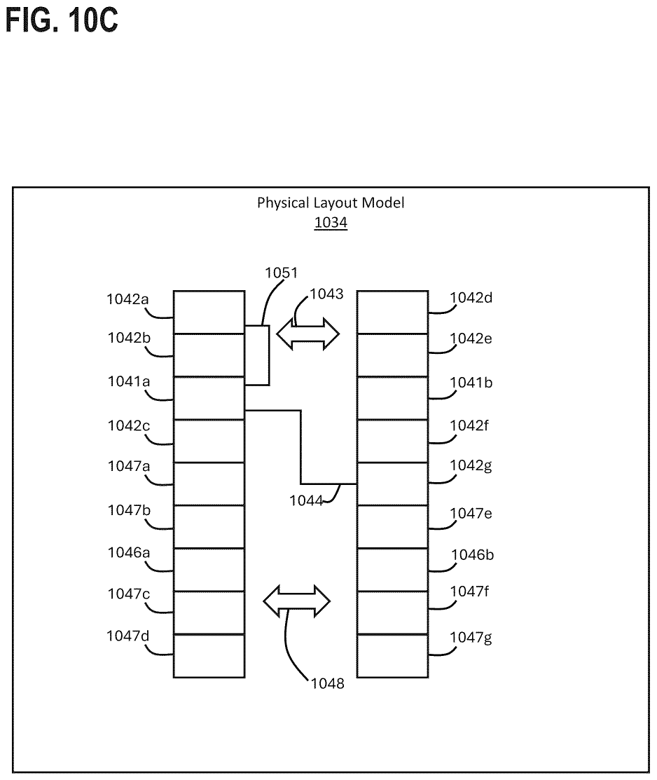

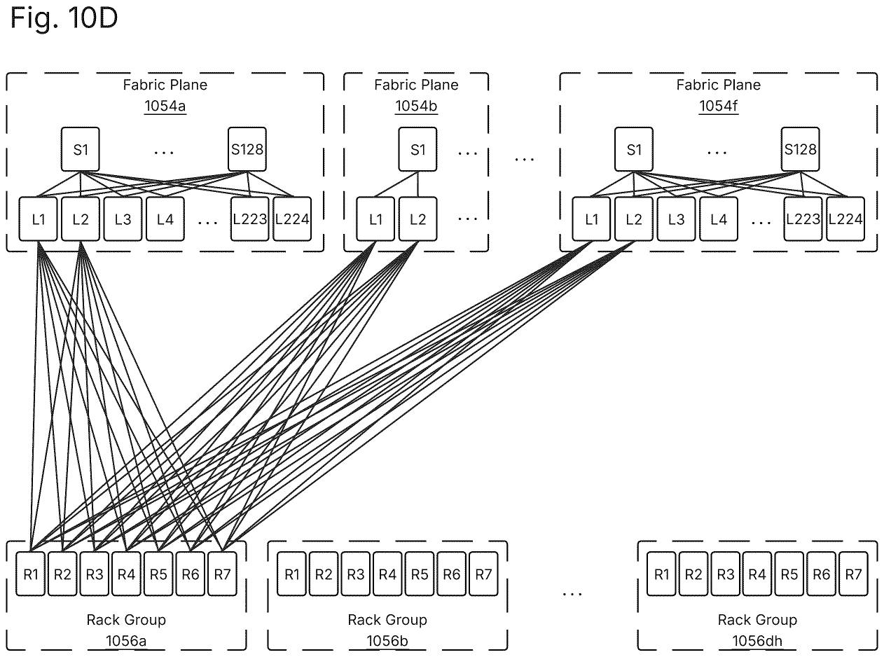

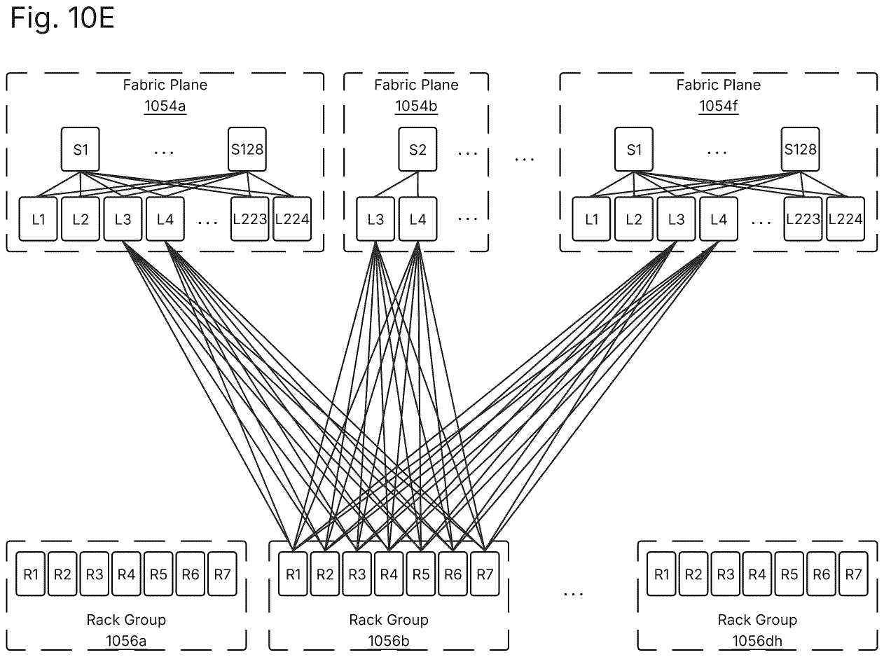

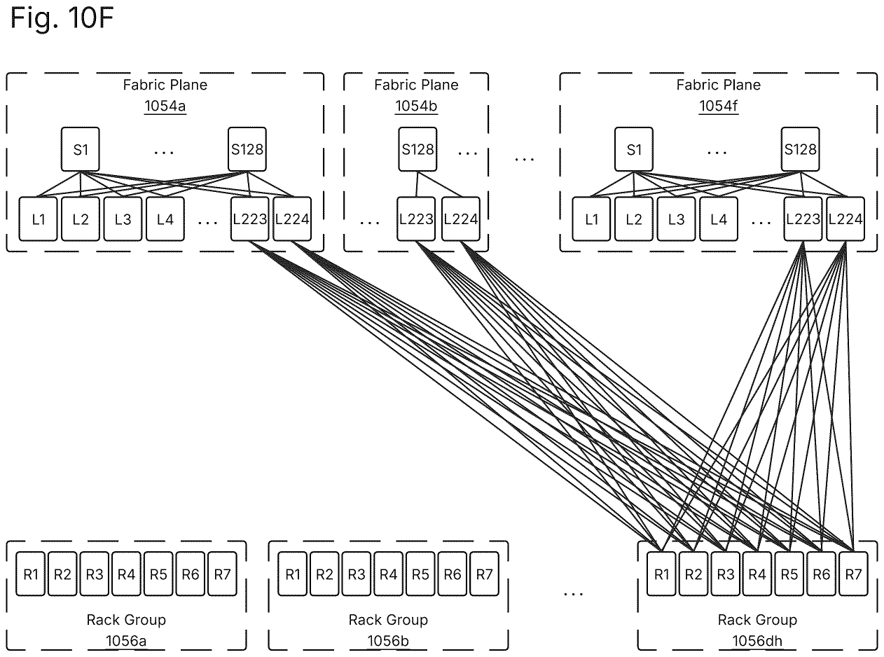

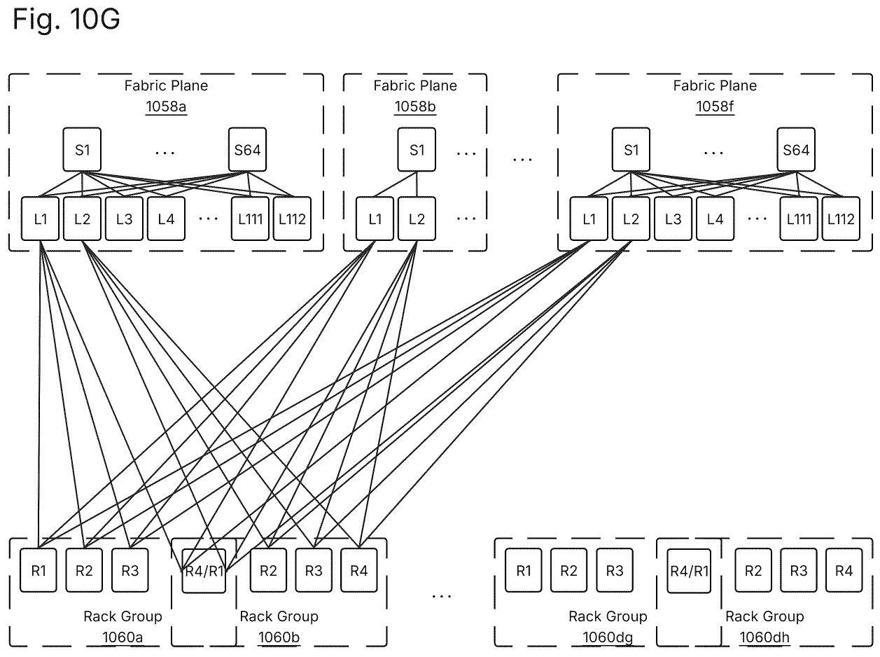

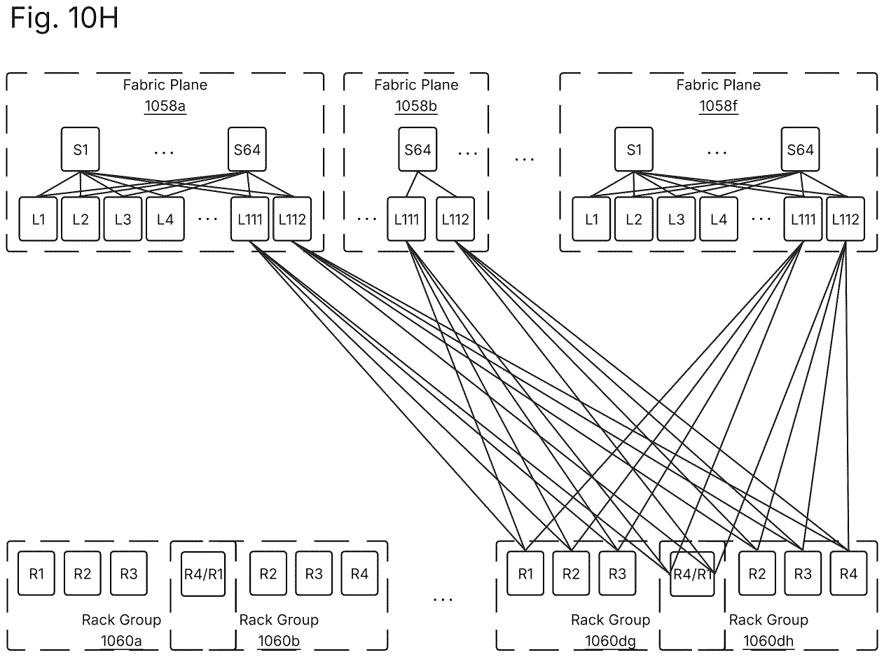

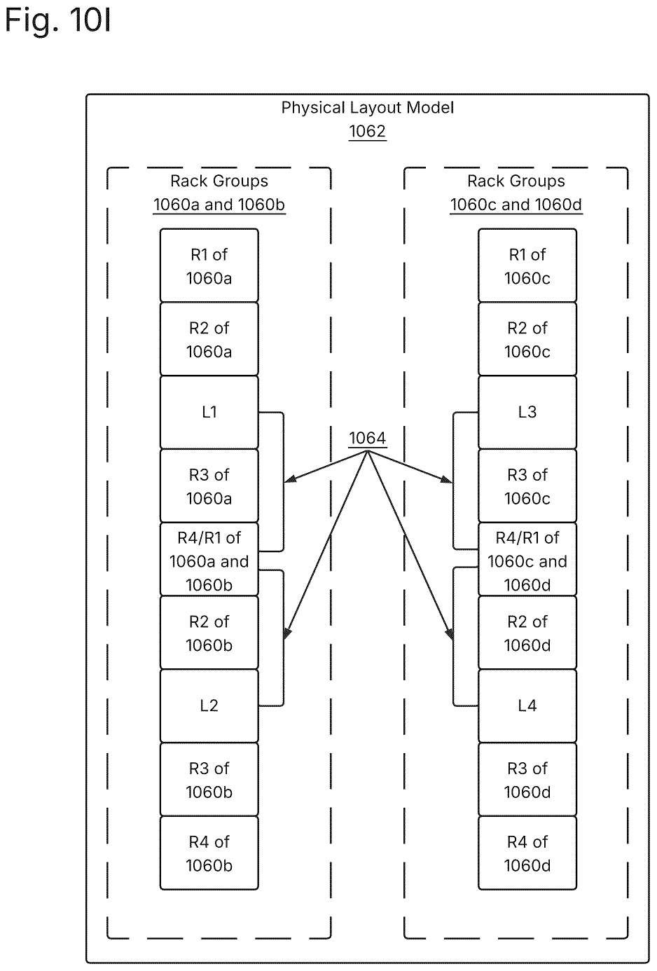

FIG. 10A illustrates a system 1000 in accordance with one or more embodiments. As illustrated in FIG. 10A, system 1000 includes a data center configuration platform 1010, a data center 1020, and a data repository 1030. In one or more embodiments, the system 1000 may include more or fewer components than the components illustrated in FIG. 10A. The components illustrated in FIG. 10A may be local to or remote from each other. The components illustrated in FIG. 10A may be implemented in software and/or hardware. Each component may be distributed over multiple applications and/or machines. Multiple components may be combined into one application and/or machine. Operations described with respect to one component may instead be performed by another component.

The data center configuration platform 1010 generates a data center model 1032. The data center model 1032 represents a configuration of network devices and client devices in the data center 1020. In embodiments, a data center model 1032 is generated based on a network topology model 1033 and a physical layout model 1034 by inserting relevant client entities and network entities. A network topology configuration engine 1012 generates the network topology model 1033 representing devices and connections between the devices. In an embodiment, the network topology model 1033 includes a set of network entities representing network devices 1021a, 1021b, 1026a, and 1026b and a set of client entities representing client devices 1022a-1022g and 1027a-1027g.

As used herein, a server rack refers to a physical or logical aggregation of computing infrastructure that may include one or more client entities and/or client devices, as illustrated in FIG. 10A-10I. The server rack may comprise rack-mounted servers, blade servers, storage arrays, virtualization hosts, or other compute platforms. In one or more embodiments, a single server rack may represent multiple logically distinct client entities operating within isolated virtual environments. Additionally, or alternatively, multiple physical client devices may be grouped within the same rack enclosure and collectively treated as a single logical client entity.

Furthermore, as used herein, a network rack refers to a physical or logical aggregation of networking infrastructure that may include one or more network entities and/or network devices, as illustrated in FIG. 10A-10I. The network rack may comprise switches, routers, firewalls, load balancers, gateways, NICs, or other communication hardware configured to manage data traffic. A network rack may represent multiple logical network domains, regardless of implementation in dedicated hardware and/or virtualized form.

A switch group refers one or more switches that operate within the same tier of the network topology model 1033. Switches within a given switch group may share common connectivity characteristics relative to the overall network architecture. For example, a switch group may consist of multiple TOR switches, spine switches, or super-spine switches. The switch group may be based on physical proximity and/or logical configuration.

A switch group association refers to a defined relationship between one or more switch groups at tier(n) and one or more switch groups at tier(m), where tier(n) and tier(m) represent different levels of the network hierarchy. Within a switch group association, a uniform connection pattern governs the interconnections between all switches in the associated groups. As an example, a Clos connection pattern is configured such that switches in switch group at tier(n) participating in the association is connected to switches in switch group at tier(m) participating in the association. As a further example, a first switch group association may include one switch group at a higher tier and two switch groups at a lower tier, where the association follows a Clos connection pattern. Under this pattern, switches in the higher-tier switch group are connected to switches in each lower-tier switch group within the association. Accordingly, switches within the higher-tier group are connected to switches within the lower-tier groups, thereby establishing a full-mesh interconnection between the higher tier and the associated lower-tier groups within the defined association.

In an embodiment, the network topology model 1033 specifies network topologies for interconnecting the network entities with client entities, and network entities with other network entities. The network topology model 1033 may specify communications connections between a network entity and a set of client entities in a client group. The network topology model 1033 may specify communications between network entities in one tier and network entities in an adjacent tier. The network topology model 1033 may specify additional types of connections, including power connections from power sources to network and client entities and cooling connections from a cooling system to the network and client entities.

A physical layout configuration engine 1013 generates a physical layout model 1034 based on the network topology model 1033. The physical layout model 1034 represents physical positions of network devices and client devices in the data center 1020 and physical connections between the devices. Additionally, or alternatively, the physical layout model 1034 may represent physical connections between racks where network devices and client devices are mounted. For example, a physical layout model 1034 that includes the line 1024 connecting block 1021a to block 1022g may represent either (a) a connector that connects a network device to a client device, or (b) a connector that connects one rack to another rack. While a length of a line connecting elements in the network topology model 1033 may be unrelated to a length of a corresponding physical connector, the length of the lines connecting elements in the physical layout model 1034 correspond to distances.

The physical layout configuration engine 1013 generates the physical layout model 1034 based on the entities and connections between the entities specified in the network topology model 1033, hardware specifications, including a hardware specification 1031, and a performance requirement specification 1035. The hardware specification 1031 may include, for example, attributes of different types of transmission lines. For example, the hardware specification 1031 specifies signal attenuation, resistance, impedance, phase velocity, phase constant, and inductance characteristics per unit length of different types of transmission lines. According to one example embodiment, the hardware specification 1031 specifies an attenuation of a copper Active Electrical Cable (AEC) type cable to connect devices in the data center. AEC cables include signal amplification and equalization circuitry built into the cable to improve signal transmission performance.

The performance requirement specification 1035 may specify requirements such as bandwidth, frequency, and signal strength required to connect devices. The physical layout configuration engine 1013 generates the physical layout model 1034 based on (a) the entities and connections specified in the network topology model 1033, the attributes of devices and transmission lines specified in the hardware specification 1031, and the performance requirements specified in the performance requirement specification 1035.

The logical relationships specified in the physical layout model 1034 are implemented physically in the data center 1020. For example, referring to FIG. 10B, the network topology model 1033 specifies two entities 1045 and 1049 that correspond to two client groups 1025 and 1029. A first client group entity 1045 corresponding to client group 1025 includes two network entities 1041a and 1041b that correspond to network devices 1021a and 1021b. The first client group entity 1045 further includes client entities 1042a-1042g that correspond to client devices 1022a-1022g. The network topology model 1033 specifies connections 1043 among the entities that correspond to the transmission lines 1023, depicted in FIG. 10A as a block arrow for purposes of illustration. In an embodiment, the network topology model 1033 specifies connections between the network entity 1041a and each client entity 1042a-1042g. The network topology model 1033 also specifies connections between the network entity 1041b and each client entity 1042a-1042g.

The second client group entity 1049 corresponding to client group 1029 includes two network entities 1046a and 1046b that correspond to network devices 1026a and 1026b. The second client group entity 1049 further includes client entities 1047a-1047g that correspond to client devices 1027a-1027g. The network topology model 1033 specifies connections 1048 among the entities that correspond to the transmission lines 1028, depicted in FIG. 10A as a block arrow for purposes of illustration.

The physical layout configuration engine 1013 converts the logical relationships represented in the network topology model 1033 into physical configurations to generate the physical layout model 1034. FIG. 10C is an example of a physical layout model 1034 according to an embodiment. Based on attributes in the hardware specification 1031 and the performance requirement specification 1035, the physical layout configuration engine 1013 determines an arrangement for entities and connection lines. For example, the network topology model 1033 represents the network entities and client entities according to communications tiers. In contrast, the physical layout model 1034 represents the network entities and client entities as being arranged in rows based on a configuration of racks in a data center. The physical layout configuration engine 1013 arranges the network entities 1041a, 1041b, 1046a, and 1046b into rows, corresponding to rows arranged in the data center 1020. The physical layout configuration engine 1013 arranges the client entities 1042a-1042g and 1047a-1047g into the rows. The physical layout configuration engine 1013 determines paths for connecting lines 1043 and 1048 such as data transmission cables. Connection line 1044 is an example of a connecting path for a data transmission cable between network entity 1041a and client entity 1042g. Connection line 1053 is another example of a connecting path for a data transmission cable between network entity 1041a and client entity 1042a.

In one or more embodiments, the physical layout configuration engine 1013 arranges a set of network entities 1041a and 1041b and client entities 1042a-1042g, that are logically connected as a client group 1045 in the network topology model 1033, into a grouping across two rows, where a longest connection path between any network entity and any client entity is shorter than a threshold length or distance. The physical layout configuration engine 1013 may determine the threshold length or distance based on (a) a connection line criteria in the hardware specification 1031 and (b) a performance requirement in the performance requirement specification 1035.

Network devices, client devices, such as graphics processing unit (GPU) servers, and transmission lines are arranged in the data center 1020 based on the configuration specified in the physical layout model 1034. In the embodiment illustrated in FIG. 10A, a first network device 1021a is arranged in one row and a network device 1021b is arranged in another row. Connection lines 1023, such as data transmission lines, physically connect the devices 1021a, 1021b, and 1022a-1022g as specified in the physical layout model 1034. For example a line connecting the network entity 1041a to the client entity 1042g in the network topology model 1033 is implemented as a physical connection line 1024 between the network device 1021a and the client device 1022g in the data center 1020.

The network topology model 1033 illustrated in FIG. 10B specifies logical relationships between network entities 1041a and 1041b and client entities 1042a-1042g in one client group 1045, and between network entities 1046a and 1046b and client entities 1047a-1047g in another client group 1049. In the embodiment illustrated in FIG. 10B, the client entities are arranged in one tier of a network fabric, and the network entities are arranged in another tier. The client entities communicate with other client entities in other client groups via the network entities. The network topology model 1033 may further identify connections 1051 and 1052 between the network entities 1041a and 1041b and other network entities. These additional network entities are omitted from FIG. 10B for purposes of clarity in describing the embodiment.

In the embodiment illustrated in FIG. 10A, transmission line 1024 represents a longest cable among a set of transmission lines 1023 connecting network devices to client devices in client group 1025. The physical layout configuration engine 1013 generates the physical layout model 1034 to arrange the network devices and client devices such that the longest cable has a length that is less than a threshold length or distance. In one embodiment, the threshold length or distance corresponds to a specified performance metric, such as a maximum allowable attenuation of a signal along a cable.

In one or more embodiments, a data repository 1030 is any type of storage unit and/or device (e.g., a file system, database, collection of tables, or any other storage mechanism) for storing data. Further, a data repository 1030 may include multiple different storage units and/or devices. The multiple different storage units and/or devices may or may not be of the same type or located at the same physical site. Further, a data repository 1030 may be implemented or executed on the same computing system as the data center configuration platform 1010. Additionally, or alternatively, a data repository 1030 may be implemented or executed on a computing system separate from the data center configuration platform 1010. The data repository 1030 may be communicatively coupled to the data center configuration platform 1010 via a direct connection or via a network.

In one or more embodiments, FIGS. 10D-10F illustrate an expanded view of the network topology model 1033 depicted in FIG. 10B, including fabric planes 1054a-1054f and rack groups 1056a-1056dh. A respective fabric plane of the fabric planes 1054a-1054f includes a plurality of network entities, including spine switches S1-S128, leaf switches L1-L224, and other fabric control components configured to forward traffic between client devices. A rack group includes a plurality of server racks R1-R7. The network entities are arranged in a multi-tier topology. As defined above, the leaf switches L1-L224 correspond to one or more switch groups, where the fabric planes 1054a-1054f define boundaries of the groups. The spine switches S1-S128 correspond to a higher tier of switches and belong to one or more switch groups within the higher tier. Server racks R1-R7 correspond to a lower tier of switches and belong to one or more switch groups. As further defined above, switches illustrated in a respective fabric plane of the fabric planes 1054a-1054f may corresponding to a switch group association. Furthermore, a rack group may form a switch group association with one or more leaf switches L1-L224 as part of a two-tier connection structure. The switch groups and switch group associations defined herein further define one or more connections depicted in the physical layout models in, at least, FIGS. 10A, 10C, and 10I. The leaf switches L1-L224 are interconnected through the spine switches S1-S128. Specifically, a leaf switch establishes bidirectional communication links with one or more of the spine switches, so traffic originating from a given leaf switch is forwarded upstream to at least one spine switch and subsequently forwarded downstream to a destination leaf switch. The connections between the spine switches and the leaf switches may be implemented using high-bandwidth physical links through which traffic flows may be distributed to reduce congestion and increase path redundancy.

In one or more embodiments, FIG. 10D also illustrates 112 rack groups, denoted as 1056a-1056dh. A rack group includes a plurality of server racks R1-R7. A rack houses one or more computing devices, networking devices, and/or storage devices. The computing devices may be configured as logical client devices with respect to the network devices in the fabric planes 1054a-1054f, so communications are initiated and received by endpoints in the rack groups. The server racks R1-R7 are logically associated as a rack group for purposes of network connectivity and management. The rack groups 1056a-1056dh are subdivided, so different rack groups are communicatively coupled to different sets of leaf switches. For example, FIG. 10D illustrates that A rack located in rack group 1056a is connected to leaf switches L1 and L2 of fabric planes 1054a-1054f. The particular division of connections between the server racks R1-R7 and the fabric planes 1054a-1054f is based on the computing devices within the server racks R1-R7.

In one or more embodiments, FIG. 10E illustrates the connections between rack group 1056b and fabric planes 1054a-1054f. Server racks R1-R7 of rack group 1056b are connected to leaf switches L3 and L4 of fabric planes 1054a-1054f. The particular division of connections between the server racks R1-R7 and the fabric planes 1054a-1054f is based on the computing devices within the server racks R1-R7 of rack group 1056b. A rack in rack group 1056b is connected to both switches L3 and L4 of fabric planes 1054a-1054f. Accordingly, FIG. 10F illustrates the connections between rack group 1056dh and fabric planes 1054a-1054f. Server racks R1-R7 of rack group 1056dh are connected to leaf switches L223 and L224 of fabric planes 1054a-1054f. The particular division of connections between the server racks R1-R7 and the fabric planes 1054a-1054f is based on the computing devices within the server racks R1-R7 of rack group 1056dh. A rack in rack group 1056dh is connected to both switches L223 and L224 of fabric planes 1054a-1054f.

In one or more embodiments, the physical layout model 1034 depicted in FIG. 10C represents physical positions of the network devices and client devices illustrated in FIGS. 10D and 10E. Specifically, FIG. 10C illustrates the connections between rack group 1056 a and fabric planes 1054a-1054f, and rack group 1056b and fabric planes 1054a-1054f. Network entities 1041a and 1041b correspond to a combination of leaf switches L1 and L2 in the fabric planes 1054a-1054f. Network entities 1046a and 1046b correspond to a combination of leaf switches L3 and L4 in the fabric planes 1054a-1054f. Client entities 1042a-1042g correspond to server racks R1-R7 in rack group 1056a and client entities 1047a-1047g correspond to server racks R1-R7 in rack group 1056b. Thus, network entities 1041a and 1041b and client entities 1042a-1042g correspond to rack group 1056a. Network entities 1046a and 1046b and client entities 1047a-1047g correspond to rack group 1056b.

In one or more embodiments, the system arranges the network entities and client entities corresponding to rack groups 1056a and 1056b, so both rack groups and corresponding entities have an inverted symmetry with respect to each other. For example, as illustrated in FIG. 10C, the system arranges components for both rack groups in two rows. For rack group 1056a, client entities 1042a-1042c and network entity 1041a are located in the first row, and client entities 1042d-1042g and network entity 1041b are located in the second row. For rack group 1056b, client entities 1047a-1047d and network entity 1046a are located in the first row, and client entities 1047e-1047g and network entity 1046b are located in the second row. Thus, three client entities corresponding to rack group 1056a and four client entities corresponding to rack group 1056b are located in the first row. Four client entities corresponding to rack group 1056a and three client entities corresponding to rack group 1056b are located in the second row. This arrangement enables the use of across the aisle connections, ensuring that space utilization is optimized and distance threshold requirements between network entities and client entities are met. For example, connection line 1044 shows the furthest distance between a network entity and client entity corresponding to rack group 1056a.

In one or more embodiments, FIGS. 10G and 10H illustrate a network topology model for an alternative arrangement that does not require across the aisle connections between the network and client entities located in different rows. FIG. 10G illustrates fabric planes 1058a-1058f and rack groups 1060a-1060dh. A respective fabric plane of the fabric planes 1058a-1058f includes a plurality of network devices, including spine switches S1-S64, leaf switches L1-L112, and other fabric control components configured to forward traffic between client devices. The network devices are arranged in a multi-tier topology. The leaf switches L1-L112 are interconnected through the spine switches S1-S64. Specifically, a leaf switch establishes bidirectional communication links with one or more of the spine switches, so traffic originating from a given leaf switch is forwarded upstream to at least one spine switch and subsequently forwarded downstream to a destination leaf switch. The connections between the spine switches and the leaf switches may be implemented using high-bandwidth physical links through which traffic flows may be distributed to reduce congestion and increase path redundancy.

In one or more embodiments, FIG. 10G also illustrates 112 rack groups, denoted as 1060a-1060dh. The rack groups include a plurality of server racks. Odd rack groups include server racks R1, R2, R3, and R4/R1. Even rack groups include server racks R4/R1, R2, R3, and R4. In both groups, rack R4/R1 operates as a shared rack. A rack houses processing resources that include one or more computing devices, networking devices, and/or storage devices. The computing devices may be configured as logical client devices with respect to the network devices in the fabric planes 1058a-1058f, so communications are initiated and received by endpoints in the rack groups. The shared rack in a rack group is divided between two adjacent rack groups by logically dividing the processing resources of the rack between the rack groups. The first portion of the processing resources is associated with a first rack group, and a second portion of the processing resources is associated with a second rack group. The shared rack operates as a member of both rack groups while maintaining logical separation of the allocated processing resources. For example, rack groups 1060a and 1060b include server racks R1-R4. However, R4 of rack group 1060a and R1 of rack group 1060b are shared from a single rack, i.e., the processing resources present in rack R4/R1 are divided in half and shared as R4 of rack group 1060a and R1 of rack group 1060b. Server racks R1-R3 of rack group 1060a are connected to leaf switch L1, and server racks R2-R4 of rack group 1060b are connected to leaf switch L2. Shared rack R4/R1 is present in both rack groups 1060a and 1060b and connected to both leaf switches L1 and L2. In particular, the “R4 side” of rack R4/R1 is connected to leaf switch L1, and the “R1 side” of rack R4/R1 is connected to leaf switch L2. In effect, rack groups 1060a and 1060b have 3½ server racks connected to leaf switches L1 and L2, respectively. FIG. 10H illustrates the connection arrangement described above for rack groups 1060dg and 1060dh. Rack R4/R1 is shared between rack groups 1060dg and 1060dh. Server racks R1-R3 of rack group 1060dg are connected to leaf switch L111, and server racks R2-R4 of rack group 1060dh are connected to leaf switch L112. Rack R4/R1 is shared between rack groups 1060dg and 1060dh and connected to both leaf switches L111 and L112.

In one or more embodiments, FIG. 10I illustrates a physical layout model 1062 that depicts rack groups 1060a-1060d (and corresponding network devices) of the network topology model shown in FIGS. 10G and 10H. The left row illustrates the physical layout of rack groups 1060a and 1060b, and the right row illustrates the physical layout of rack groups 1060c and 1060d. The left and right rows may be spaced apart from each other. The order of devices in the left row is as follows: (1) R1 of rack group 1060a, (2) R2 of rack group 1060a, (3) leaf switches L1, (4) R3 of rack group 1060a, (5) shared rack group R4/R1 of rack groups 1060a and 1060b, (6) R2 of rack group 1060b, (7) leaf switches L2, (8) R3 of rack group 1060b, and (9) R4 of rack group 1060b. As such, the left row depicts connections between the rack groups 1060a and 1060b and fabric planes shown in FIG. 10G. The right row mirrors the arrangement of the left row but for rack groups 1060c and 1060d. The order of the devices in the right row are as follows: (1) R1 of rack group 1060c, (2) R2 of rack group 1060c, (3) leaf switches L3, (4) R3 of rack group 1060c, (5) shared rack group R4/R1 of rack groups 1060c and 1060d, (6) R2 of rack group 1060d, (7) leaf switches L4, (8) R3 of rack group 1060d, and (9) R4 of rack group 1060d. This arrangement of two rack groups per row, with the rack groups including 3½ server racks per group, ensures that space utilization is optimized and distance threshold requirements between network devices, and client devices are met without the use of cross-the-aisle connections. In addition, this arrangement reduces the size of a rack group, allowing for a more compact physical footprint by eliminating the need to have cross-the-aisle connections. For example, connection lines 1064 depict the furthest distance between a leaf switch and a corresponding rack. Rack groups correspond to one or more server racks, client entities, and/or switch groups and leaf switches correspond to one or more network racks and/or network entities. Based on respective connections between the elements depicted in FIG. 10I, one or more switch group associations may be formed. For example, a rack group including 3½ server racks and connected leaf switches correspond to a switch group association. Thus, a row corresponding to rack groups 1060a and 1060b may include two switch group associations. Similarly, a row corresponding to rack groups 1060c and 1060d may include two switch group associations.

In an embodiment, data center configuration platform 1010 is implemented on one or more digital devices. The term “digital device” generally refers to any hardware device that includes a processor. A digital device may refer to a physical device executing an application or a virtual machine. Examples of digital devices include a computer, a tablet, a laptop, a desktop, a netbook, a server, a web server, a network policy server, a proxy server, a generic machine, a function-specific hardware device, a hardware router, a hardware switch, a hardware firewall, a hardware firewall, a hardware network address translator (NAT), a hardware load balancer, a mainframe, a television, a content receiver, a set-top box, a printer, a mobile handset, a smartphone, a personal digital assistant (PDA), a wireless receiver and/or transmitter, a base station, a communication management device, a router, a switch, a controller, an access point, and/or a client device.

In one or more embodiments, interface 1014 refers to hardware and/or software configured to facilitate communications between a user and the data center configuration platform 1010. Interface 1014 renders user interface elements and receives input via user interface elements. Examples of interfaces include a graphical user interface (GUI), a command line interface (CLI), a haptic interface, and a voice command interface. Examples of user interface elements include checkboxes, radio buttons, dropdown lists, list boxes, buttons, toggles, text fields, date and time selectors, command lines, sliders, pages, and forms.

In an embodiment, different components of interface 1014 are specified in different languages. The behavior of user interface elements is specified in a dynamic programming language such as JavaScript. The content of user interface elements is specified in a markup language, such as hypertext markup language (HTML) or XML User Interface Language (XUL). The layout of user interface elements is specified in a style sheet language such as Cascading Style Sheets (CSS). Alternatively, interface 1014 is specified in one or more other languages, such as Java, C, or C++.

### Generating and Implementing a Data Center Model Including Cross-Row Client Groups

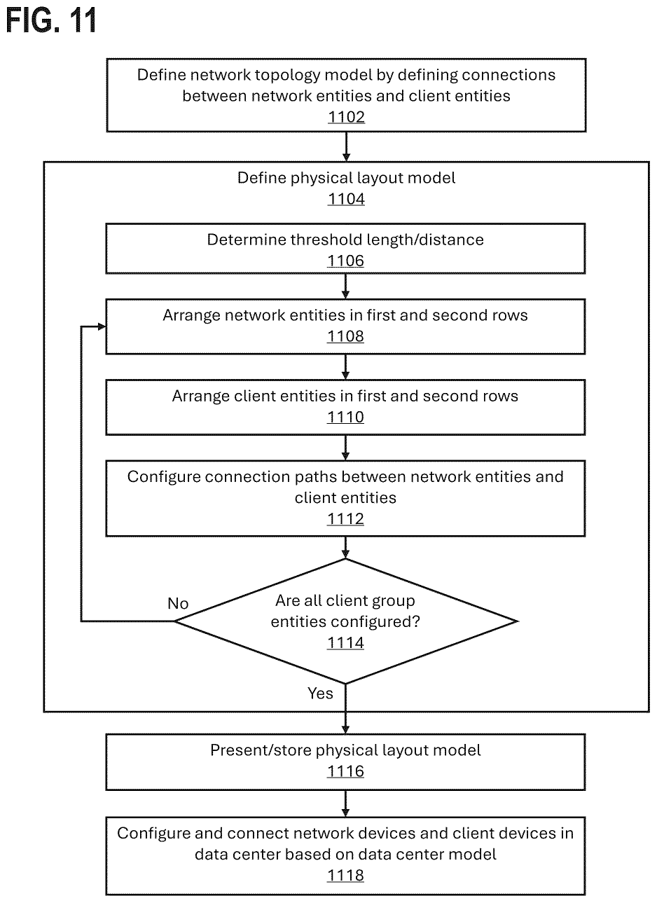

FIG. 11 illustrates an example set of operations for generating and implementing a data center model including cross-row client groups in accordance with one or more embodiments. One or more operations illustrated in FIG. 11 may be modified, rearranged, or omitted. Accordingly, the particular sequence of operations illustrated in FIG. 11 should not be construed as limiting the scope of one or more embodiments.

In an embodiment, the system defines a network topology model by defining connections between network entities and client entities (Operation 1102). The network topology model specifies one or more client group entities. Client group entities include one or more network entities, representing network devices such as network switches, and sets of client entities, such as servers. In a client group entity, the client entities communicate with other client entities via the network entities.

In one or more embodiments, the network topology describes a network fabric. The fabric describes network entities, their connections with other network entities, and routing policies associated with the network entities. As discussed above, network entities in the network topology model may represent physical network switches. Examples of fabrics include compute fabrics (CFAB) and other fabrics such as JFAB and MFAB. A network fabric represented in the network topology model may use a Clos topology. A Clos topology is a network design that utilizes multiple layers of switches to create a highly scalable, fault-tolerant network. Clos topologies utilize a multi-stage switching architecture where each stage connects to all nodes in the next stage, allowing for efficient data flow between numerous devices with minimal latency.

In one example, the network topology model describes a CFAB. The CFAB in the network topology model represents a cluster of commodity switches arranged in a three-tier Clos topology that can provide non-blocking, full-bisectional bandwidth. The CFAB includes tier one (T1) and tier two (T2) switches in every client group entity. When implemented in a physical data center, T1 switches connect “down” to Top-of-Rack (ToR) switches in compute racks and “up” to T2 switches, while T2 switches connect “down” to T1 switches and “up” to T3 switches.

In another example, the network topology model describes a JFAB. The JFAB connects CFABs to each other and to other sites.

The system generates a physical layout model based on the network topology model (Operation 1104). Generating the physical layout model includes determining a threshold length or distance (Operation 1106). For example, a performance specification may specify that a connection between two devices must meet a performance metric, such as a defined signal strength, a defined signal-to-noise (S/N) ratio, or a defined attenuation level. The system may determine cable lengths that correspond to the performance metric requirement to determine the threshold length/distance. For example, in addition to being lower cost and consuming less power, copper AEC type cables generally provide better signal integrity than active optical cables (AOCs) up to approximately 7 meters in distance. The system may determine that, based on properties of AEC, for an AEC type cable to meet an attenuation or power requirement, the AEC should not exceed 7 meters. However, the system may use other threshold lengths depending on the characteristics of the cables or transceiver technology used in the physical layout model.

The system arranges network entities in first and second rows (Operation 1108). For example, the system may determine that a client group entity, including client entities connected to network entities, includes two network entities and seven client entities. The network entities in the network topology may represent network switches. The client entities in the network topology may represent servers or other computing devices. The system arranges one network entity of a client group entity into one row and the other network entity into another row.

The system arranges client entities in the first and second rows (Operation 1110). The system may arrange the client entities into the rows based on the threshold length or distance. For example, the system may determine that arranging a client entity a particular distance from a network entity would result in a connection between the client entity and the network entity that would exceed the threshold length/distance. Instead, the system may arrange the client entity in a row across from the network entity to meet, or fall below, the threshold length/distance.

In an embodiment where a client group entity includes two network entities and seven client entities, the system may arrange a client group entity with three client entities in one row and four client entities in another row. The system may further arrange client group entities adjacent to each other to optimize space utilization while meeting distance threshold requirements. In one embodiment, the system arranges one client group entity adjacent to another client group entity configured to have inverted symmetry with each other. For example, one client group entity may include three client entities in a first row and four client entities in a second row. Another client group entity may have four client entities in the first row and three client entities in the second row.

The system configures connection paths between network entities and client entities (Operation 1112). Connection paths may correspond to paths between ports of corresponding devices. Alternatively, connection paths may correspond to paths between blocks in a physical layout model representing racks in which devices are mounted. The connection paths represent, in the physical layout model, physical paths in a data center. For example, if a data center utilizes defined conduit paths to run cables, cords, and tubes, the connection paths in the physical layout model follow the conduit paths in the data center.

Based on the arrangement of network entities and client entities, the connection paths satisfy the threshold length or distance requirement. In embodiments, a longest connection path between a network entity and any client entity in the same client group is less than the threshold length/distance.

In one embodiment, the system configures network entities and client entities of a client group entity to be within a particular fabric group in a network topology. The system may refrain from connecting the client group entity to additional fabric groups. Alternatively, the system may configure the client group entity such that its network entities are connected to network entities of other fabric groups in the network topology.

The system determines if all client groups specified in a network topology model are configured in the physical layout model (Operation 1114). A network topology model may specify multiple client group entities. The system may configure the client group entities in the physical layout model individually, in pairs, or in other groupings. For example, the system may determine a number of client group entities capable of being arranged in two rows. The system may configure the arrangements of network entities, client entities, and connection paths for the client group entities capable of being arranged in two rows at the same time. The system may configure additional sets of client group entities arranged in different pairs of rows in subsequent configuration operations.

If the system determines all client groups in a network topology model are configured in the physical layout model, the system presents and/or stores the physical layout model (Operation 1116). Presenting and storing the physical layout model may include, for example, displaying a layout diagram on a display device, printing out a layout diagram on paper, and storing layout data in a storage device.

Operators configure and connect network devices and client devices in a data center based on the physical layout model (Operation 1118). Configuring and connecting the network devices includes mounting network devices and client devices into racks that are positioned in a manner represented in the physical layout model. Connecting the network devices and client devices further includes running cable between devices and/or racks storing the devices along connection paths based on the connection paths specified in the physical layout model.

Information describing the hardware specification 1031, the data center model 1032, and the performance requirement specification 1035 may be implemented across any of components within the system 1000. However, this information is illustrated within the data repository 1030 for purposes of clarity and explanation.

In one or more embodiments, data center configuration platform 1010 refers to hardware and/or software configured to perform operations described herein for generating and implementing a data center model for configuring cross-row client groups. Examples of operations for generating and implementing a data center model for configuring cross-row client groups are described below with reference to FIG. 11.

### Example Embodiment

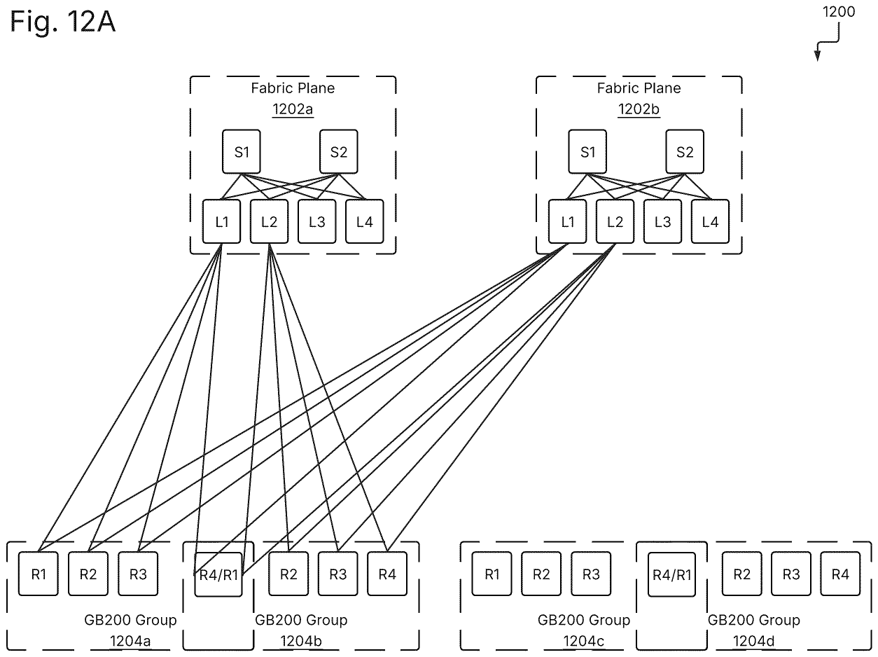

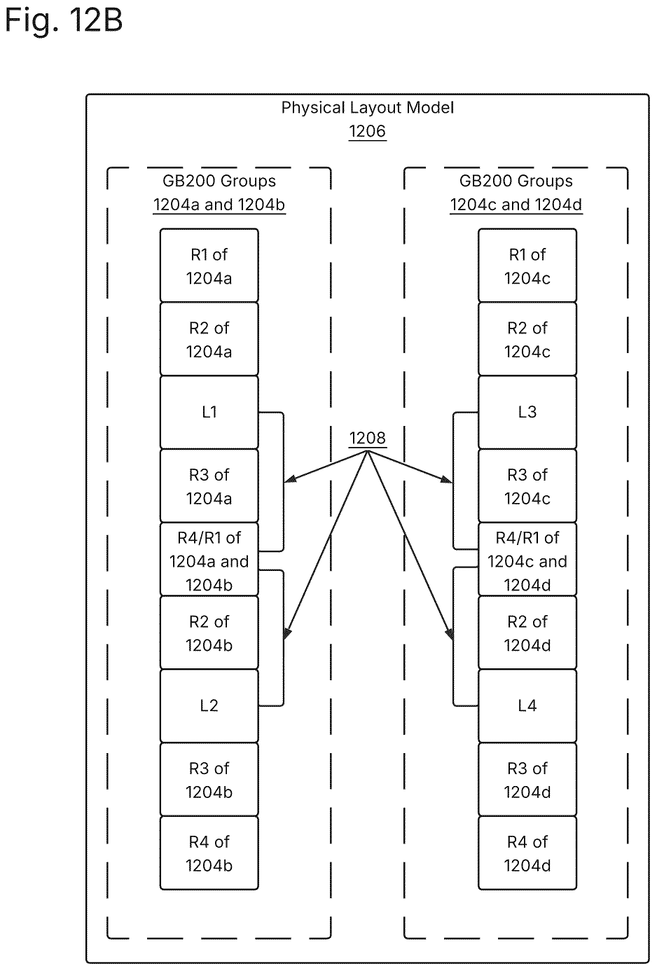

FIGS. 12A and 12B illustrate an example embodiment generating and implementing a data center model including cross-row client groups. The example embodiment is described below for purpose of clarity. Components and/or operations described below should be understood as one specific example that may not be applicable to certain embodiments. For example, the data center model design is not specific or limited to GB200 GPU racks. Accordingly, components and/or operations described below should not be construed as limiting the scope of any of the claims.

In one or more embodiments, a data center is designed in response to deployment requirements identified by John, a principal infrastructure architect responsible for deploying a new GPU compute cluster. John works with Maria, a network engineer, and Alex, a data center operations manager, to define requirements for both network entities and client entities within the data center.

John specifies that the data center is required to support large-scale GPU workloads using RDMA over Converged Ethernet (RoCE) with predictable network latency between any two GPU systems. Maria further requires that the network fabric should avoid optical connections due to cost and power constraints and, instead, rely on copper cabling with a maximum allowable cable length of seven meters. Alex adds a physical constraint that the deployment is required to fit within two adjacent rows of racks to simplify installation and maintenance.

Based on these requirements, the system identifies the client entities as GB200 GPU racks, a rack including multiple GPU compute nodes equipped with RDMA-capable Ethernet network interface cards (NICs). The network entities are identified as Ethernet switches capable of supporting RoCE traffic and high bandwidth forwarding. As illustrated in FIG. 12A, the system generates a network topology model 1200 for the data center. The topology model 1200 specifies a Clos-based fabric that includes leaf switches L1-L4 and spine switches S1 and S2 across two fabric planes 1202a and 1202b. The topology model 1200 also specifies four GB200 groups 1204a-1204d with a GB200 group including 3½ GB200 GPU racks. The three full GB200 GPU racks in a GB200 group are connected to a single leaf. For example, GB200 GPU racks R1-R3 in GB200 group 1204a are connected to leaf switch L1, and GB200 GPU racks R2-R4 in GB200 group 1204b are connected to leaf switch L2. The GB200 GPU rack labeled R4/R1 is divided, so half of the GPU compute nodes belong to GB200 group 1204a and the other half belong to GB200 group 1204b. The half belonging to GB200 group 1204a are connected to leaf switch L1, and the other half belonging to GB200 group 1204b are connected to leaf switch L2. Although not depicted in FIG. 12A, GB200 groups 1204c and 1204d are equivalently connected to leaf switches L3 and L4.

After placement decisions are finalized, the system configures the physical network connections to implement the topology model. Using the topology model and the seven-meter cable-length constraint, the system derives a physical layout model 1206 as illustrated in FIG. 12B. A GPU compute node is connected to its assigned leaf switches using passive copper direct-attach cables shorter than seven meters. A leaf switch is connected to each of the four spine switches using passive copper cables routed through overhead trays with all cable lengths satisfying the distance threshold defined by the physical layout model. The system generates a physical layout model 1206 to determine allowable rack positions for the GB200 GPU racks within the GB200 groups 1204a-1204d and leaf switches L1-L4, so no required physical connection exceeds the distance threshold. The system arranges the devices in a two-row physical configuration with the first row corresponding to GB200 groups 1204a and 1204b and the second row corresponding to GB200 groups 1204c and 1204d. The order of devices in the left row is as follows: (1) R1 of GB200 group 1204a, (2) R2 of GB200 group 1204a, (3) leaf switches L1, (4) R3 of GB200 group 1204a, (5) shared GB200 group R4/R1 of GB200 groups 1204a and 1204b, (6) R2 of GB200 group 1204b, (7) leaf switches L2, (8) R3 of GB200 group 1204b, and (9) R4 of GB200 group 1204b. As such, the left row depicts connections between the GB200 groups 1204a and 1204b and fabric planes shown in FIG. 10G. The right row mirrors the arrangement of the left row but for GB200 groups 1204c and 1204d. The order of the devices in the right row are as follows: (1) R1 of GB200 group 1204c, (2) R2 of GB200 group 1204c, (3) leaf switches L3, (4) R3 of GB200 group 1204c, (5) shared GB200 group R4/R1 of GB200 groups 1204c and 1204d, (6) R2 of GB200 group 1204d, (7) leaf switches L4, (8) R3 of GB200 group 1204d, and (9) R4 of GB200 group 1204d. GB200 groups correspond to one or more server racks and/or client entities and leaf switches correspond to one or more network racks and/or network entities. Based on respective connections between the elements depicted in FIG. 12B, one or more switch group associations may be formed. For example, a rack group including 3½ server racks and connected leaf switches correspond to a switch group association. Thus, a row corresponding to rack groups 1204a and 1204b may include two switch group associations. Similarly, a row corresponding to rack groups 1204c and 1204d may include two switch group associations.

During operation, the GB200 GPU racks function as client devices that initiate RDMA communications over the fabric, while the leaf switches L1-L4 and spine switches S1 and S2 function as network devices within fabric planes 1202a and 1202b that forward traffic between racks and rack groups. Communication between GB200 GPU racks in different GB200 groups traverses a fixed number of inter-switch hops through the leaf and spine switches, providing predictable latency that satisfies the original requirements defined by John and the deployment team.

By starting from explicit operational requirements identified by John, Maria, and Alex, the system systematically derives the network topology, physical layout, devices placement, and physical connections. As such, the system generates a data center that efficiently supports high-performance GPU workloads using short-reach copper cabling.

### Miscellaneous; Extensions

Unless otherwise defined, all terms (including technical and scientific terms) are to be given their ordinary and customary meaning to a person of ordinary skill in the art, and are not to be limited to a special or customized meaning unless expressly so defined herein.

This application may include references to certain trademarks. Although the use of trademarks is permissible in patent applications, the proprietary nature of the marks should be respected and every effort made to prevent their use in any manner which might adversely affect their validity as trademarks.

Embodiments are directed to a system with one or more devices that include a hardware processor and that are configured to perform any of the operations described herein and/or recited in any of the claims below.

In an embodiment, one or more non-transitory computer readable storage media comprises instructions which, when executed by one or more hardware processors, cause performance of any of the operations described herein and/or recited in any of the claims.

In an embodiment, a method comprises operations described herein and/or recited in any of the claims, the method being executed by at least one device including a hardware processor.

Any combination of the features and functionalities described herein may be used in accordance with one or more embodiments. In the foregoing specification, embodiments have been described with reference to numerous specific details that may vary from implementation to implementation. The specification and drawings are, accordingly, to be regarded in an illustrative rather than a restrictive sense. The sole and exclusive indicator of the scope of patent protection, and what is intended by the applicants to be the scope of patent protection, is the literal and equivalent scope of the set of claims that issue from this application, in the specific form in which such claims issue, including any subsequent correction.

What is claimed is:

1. A system comprising:
a first plurality of racks comprising:
a first plurality of server racks;
a second plurality of server racks;
a first network rack; and
a second network rack;
wherein the first plurality of racks are arranged in a first row in a data center;
a second plurality of racks comprising:
a third plurality of server racks;
a fourth plurality of server racks;
a third network rack; and
a fourth network rack;
wherein the second plurality of racks are arranged in a second row in a data center;
a first plurality of cabling running between the third plurality of server racks of the second row and the first network rack of the first row;
a second plurality of cabling running between the second plurality of server racks of the first row and the fourth network rack of the second row;
a third plurality of cabling running between the second plurality of server racks of the first row and the second network rack of the first row;
a fourth plurality of cabling running between the third plurality of server racks of the second row and the third network rack of the second row.

2. The system of claim 1, further comprising:
a first switch group association, wherein the first switch group association comprises a first set of switch groups of a first tier and a second set of switch groups of a second tier;
a second switch group association wherein the second switch group association comprises a third set of switch groups of the first tier and a fourth set of switch groups the second tier;
a third switch group association, wherein the third switch group association comprises one or more switch groups from the first set of switch groups, one or more switch groups from the third set of switch groups, and a fifth switch group from a third tier, wherein the third tier is lower than the first tier and the second tier;
wherein switches of the third switch group association are located in the first row and the second row.

3. The system of claim 1, wherein the first plurality of server racks and the second plurality of server racks in the first row have an inverted symmetry with respect to the third plurality of server racks and the fourth plurality of server racks in the second row.

4. The system of claim 1, further comprising:
arranging the first plurality of racks and the second plurality of racks in the data center such that a longest cable of the first plurality of cabling, the second plurality of cabling, the third plurality of cabling, and the fourth plurality of cabling has a length less than a threshold distance.

5. The system of claim 4, wherein the threshold distance is determined based on one or more data transmission characteristics of the first plurality of cabling, the second plurality of cabling, the third plurality of cabling, and the fourth plurality of cabling.

6. A system comprising:
a plurality of racks comprising:
a first network rack;
a second network rack;
one or more first server racks connected to the first network rack;
one or more second server racks connected to the second network rack; and
a third server rack connected to the first network rack and the second network rack;
wherein the plurality of racks are arranged in a row in a data center;
a first plurality of cabling running between a first subset of servers within the third server rack and one or more first switches in the first network rack;
a second plurality of cabling running between a second subset of servers within the third server rack and one or more second switches in the second network rack;
wherein the first subset of servers are not connected to the one or more switches in the second network rack;
wherein the second subset of servers are not connected to the one or more switches in the first network rack.

7. The system of claim 6, further comprising:
a first switch group association comprising a first set of switch groups of a first tier and a second set of switch groups of a second tier;
a second switch group association comprising a third set of switch groups of the first tier and a fourth set of switch groups of the second tier;
a third switch group association comprising one or more switch groups of the first switch group association and one or more switch groups of a fifth set of switch group from a third tier that is lower than the first tier and the second tier;
a fourth switch group association comprising one or more switch groups of the second switch group association and one or more switch groups of a sixth set of switch group from the third tier;
wherein switches of the third switch group association and switches of the fourth switch group association are included in the row in the data center.

8. The system of claim 6, further comprising:
arranging the plurality of racks in the data center such that a longest cable of the first plurality of cabling and the second plurality of cabling has a length less than a threshold distance.

9. The system of claim 8, wherein the threshold distance is determined based on one or more data transmission characteristics of the first plurality of cabling and the second plurality of cabling.

10. A method comprising:
defining a network topology in a data center model, wherein defining the network topology comprises:
inserting, into the data center model, a first plurality of client entities representing a first plurality of client devices and a first set of one or more network entities representing a first set of one or more network devices,
wherein the first plurality of client entities are associated with a first client group, and
wherein each of the first plurality of client entities in the first client group is connected to each of the first set of one or more network entities;
defining a physical layout in the data center model, wherein defining the physical layout comprises:
arranging the first client group into one or more rows in the physical layout; and
arranging the first set of one or more network entities into the one or more rows in the physical layout; and
generating the data center model comprising the network topology and the physical layout, wherein the data center model indicates connections and positions of the first plurality of client devices and the first set of one or more network devices in a data center.

11. The method of claim 10, wherein arranging the first client group and the first set of one or more network devices in the physical layout is responsive to determining that a longest connection path between positions for a first client device and positions for the first set of one or more network devices is less than a threshold distance.

12. The method of claim 11, wherein the threshold distance is based on a data transmission criteria of one or more cables implementing connections between each of the first plurality of client entities and the first set of one or more network entities.

13. The method of claim 10, wherein the first set of one or more network entities are within a first fabric group in the network topology, and the first client group is connected with the first fabric group, without connecting to a second fabric group in the network topology.

14. The method of claim 10, wherein the first set of one or more network entities are within multiple fabric groups in the network topology, and the first client group is connected with a subset of network entities of each of the multiple fabric groups in the network topology.

15. The method of claim 10, wherein defining the physical layout further comprises:
arranging a second client group into the one or more rows in the physical layout;
arranging a second set of one or more network entities into the one or more rows in the physical layout;
wherein each of a second plurality of client entities in the second client group is connected to the second set of one or more network entities.

16. The method of claim 15, wherein the first client group is arranged across a plurality of rows in the physical layout and the second client group is arranged across a plurality of rows in the physical layout;
wherein an arrangement of the first client group across the plurality of rows and an arrangement of the second client group across the plurality of rows have inverted symmetry with each other.

17. The method of claim 10, wherein the defining the network topology further comprises:
inserting, into the data center model, a second plurality of client entities representing a second plurality of client devices and a second set of one or more network entities representing a second set of one or more network devices;
inserting, into the data center model, a third client entity representing a third client device;
wherein the second plurality of client entities are associated with a second client group;
wherein the third client entity is associated with the first client group and the second client group;
wherein each of the second plurality of client entities in the second client group is connected to each of the second set of one or more network entities;
wherein the third client entity is connected to the first set of one or more network entities and the second set of one or more network entities.

18. The method of claim 10, wherein the connections of the first plurality of client devices and the first set of one or more network devices in the data center are implemented based on the data center model, and the connections comprise a cross-the-aisle connection between the plurality of rows.
